(19) United States
(12) Patent Application Publication
(10) Pub. No.: US 2026/0231626 A1
(43) Pub. Date: Aug. 6, 2026

(54) DISPLAY DEVICE, METHOD OF PROVIDING THE SAME, AND ELECTRONIC DEVICE INCLUDING THE SAME

(71) Applicant: Samsung Display Co., LTD., Yongin-si (KR)

(72) Inventor: HYUNEOK SHIN, Yongin-si (KR)

(21) Appl. No.: 19/295,784

(22) Filed: Aug. 11, 2025

(30) Foreign Application Priority Data
Feb. 3, 2025 (KR) 10-2025-0012949

(51) Int. Cl. H10K 59/123; H10K 50/813; H10K 50/816; H10K 59/12; H10K 59/35; H10K 102/00; H10K 102/10

(52) U.S. Cl. CPC H10K 59/123; H10K 50/813; H10K 50/816; H10K 59/1201; H10K 59/35; H10K 2102/101; H10K 2102/351

(57) ABSTRACT

A display device includes light emitting elements in sub-pixel areas emitting different color lights from each other, a light emitting element among the light emitting elements which is in a sub-pixel area among the sub-pixel areas includes an anode, a light-emitting layer which is on the anode. The anode includes a pixel electrode, a thickness compensation pattern overlapping the pixel electrode and including a first insulating pattern, a first conductive pattern, a second insulating pattern and a second conductive pattern in order from the first pixel electrode, and an anode connection pattern which covers a side surface of the thickness compensation pattern and electrically connects the pixel electrode, the first conductive pattern and the second conductive pattern to each other. The second conductive layer of the anode is exposed to outside the anode and is in contact the light-emitting layer.

This application claims priority to Korean Patent Application No. 10-2025-0012949, filed on Feb. 3, 2025, and all the benefits accruing therefrom under 35 U.S.C. § 119, the content of which is herein incorporated by reference in its entirety.

### BACKGROUND

### 1. Field

The present disclosure relates generally to a display device. More particularly, the present disclosure relates to a display device, a method of manufacturing (or providing) the display device, and an electronic device including the display device.

### 2. Description of the Related Art

With the development of information technology, the importance of a display device as a connection medium between a user and information, has been highlighted. For example, the use of display devices such as liquid crystal display (LCD) device, organic light emitting diode (OLED) display device, plasma display panel (PDP) device, quantum dot display device or the like is increasing.

The display device includes a light-emitting element, where the light-emitting element includes a pixel electrode, a common electrode, and a light-emitting layer arranged between the pixel electrode and the common electrode. In order to improve the light efficiency of the light-emitting element, functional layers (e.g., a hole transport layer, an electron transport layer, or the like) may be further arranged on top and/or bottom of the light-emitting layer.

### SUMMARY

In a display device which implements full color, a resonance thickness of light may be controlled for each sub-pixel of different colors (e.g., red, green, and blue sub-pixels) to increase the intensity of light of different wavelengths for each of the sub-pixels.

Embodiments provide a display device with improved light efficiency and element reliability.

Embodiments provide a method of manufacturing (or providing) the display device.

Embodiments provide an electronic device including the display device.

A display device according to an embodiment of the present disclosure includes: a substrate including a first sub-pixel area, a second sub-pixel area, and a third sub-pixel area, a first pixel electrode arranged in the first sub-pixel area on the substrate, a second pixel electrode arranged in the second sub-pixel area on the substrate, a third pixel electrode arranged in the third sub-pixel area on the substrate, a first thickness compensation pattern overlapping the third sub-pixel area and including a first insulating pattern, a first conductive pattern, a second insulating pattern, and a second conductive pattern which are sequentially stacked on the third pixel electrode, a first anode connection pattern arranged on the third pixel electrode, covering a side surface of the first thickness compensation pattern, and contacting the third pixel electrode, the first conductive pattern, and the second conductive pattern, a first light-emitting layer arranged on the first pixel electrode and configured to emit a first light, a second light-emitting layer arranged on the second pixel electrode and configured to emit a second light having a different color from the first light, and a third light-emitting layer arranged on the third pixel electrode and configured to emit a third light having a different color from the first light and the second light.

In an embodiment, a thickness of the first insulating pattern and a thickness of the second insulating pattern may be greater than a thickness of the first conductive pattern and a thickness of the second conductive pattern.

In an embodiment, each of the first insulating pattern and the second insulating pattern may include a silicon oxide. Each of the first conductive pattern and the second conductive pattern may include a transparent conductive oxide.

In an embodiment, the first anode connection pattern may entirely surround the first thickness compensation pattern in a plan view.

In an embodiment, the first anode connection pattern may contact an edge of the third pixel electrode and may be spaced apart from a central portion of the third pixel electrode in a plan view.

In an embodiment, a side surface of the first conductive pattern may protrude more in a direction away from a center of the first thickness compensation pattern than a side surface of the first insulating pattern. A side surface of the second conductive pattern may protrude more in the direction away from the center of the first thickness compensation pattern than a side surface of the second insulating pattern.

In an embodiment, the first anode connection pattern may contact a lower surface of the first conductive pattern and a lower surface of the second conductive pattern.

In an embodiment, the display device may further include: a second thickness compensation pattern overlapping the second sub-pixel area and including a third insulating pattern and a third conductive pattern which are sequentially stacked on the second pixel electrode, and a second anode connection pattern arranged on the second pixel electrode, covering a side surface of the second thickness compensation pattern, and contacting the second pixel electrode and the third conductive pattern.

In an embodiment, the first insulating pattern and the third insulating pattern may include a same material. The first conductive pattern and the third conductive pattern may include a same material.

In an embodiment, the second anode connection pattern may be spaced apart from an upper surface of the second thickness compensation pattern.

In an embodiment, the second thickness compensation pattern may further include: a residual insulating pattern arranged on the third conductive pattern and overlapping an edge of the third conductive pattern, and a residual conductive pattern arranged on the residual insulating pattern.

In an embodiment, the second anode connection pattern may overlap an entirety of the residual insulating pattern and an entirety of the residual conductive pattern in a plan view.

In an embodiment, the first light-emitting layer may overlap the first sub-pixel area, the second light-emitting layer may overlap the first to third sub-pixel areas, and the third light-emitting layer may overlap the third sub-pixel area.

A method of manufacturing a display device according to an embodiment of the present disclosure includes: forming a first pixel electrode overlapping a first sub-pixel area, a second pixel electrode overlapping a second sub-pixel area, and a third pixel electrode overlapping a third sub-pixel area on a substrate, the substrate including the first sub-pixel area, the second sub-pixel area, and the third sub-pixel area, forming a first preliminary insulating layer covering the first to third pixel electrodes on the substrate, sequentially forming a first preliminary conductive layer, a second preliminary insulating layer, and a second preliminary conductive layer on the first preliminary insulating layer, etching the first preliminary insulating layer, the first preliminary conductive layer, the second preliminary insulating layer, and the second preliminary conductive layer through a first etching process to form a first thickness compensation pattern overlapping the third sub-pixel area and including a first insulating pattern, a first conductive pattern, a second insulating pattern, and a second conductive pattern which are sequentially stacked on the third pixel electrode, forming an anode connection pattern covering a side surface of the first thickness compensation pattern and contacting the third pixel electrode, the first conductive pattern, and the second conductive pattern, forming a first light-emitting layer configured to emit a first light on the first pixel electrode, forming a second light-emitting layer configured to emit a second light having a different color from the first light on the second pixel electrode, and forming a third light-emitting layer configured to emit a third light having a different color from the first light and the second light on the third pixel electrode.

In an embodiment, a thickness of the first preliminary insulating layer and a thickness of the second preliminary insulating layer may be greater than a thickness of the first preliminary conductive layer and a thickness of the second preliminary conductive layer.

In an embodiment, the method may further include removing a portion of a side surface of the first insulating pattern and a portion of a side surface of the second insulating pattern through an additional etching process after forming the first thickness compensation pattern.

In an embodiment, the etching the first preliminary insulating layer, the first preliminary conductive layer, the second preliminary insulating layer, and the second preliminary conductive layer through the first etching process may include forming a third insulating pattern, a third conductive pattern, a fourth insulating pattern, and a fourth conductive pattern which overlap the second sub-pixel area and are sequentially stacked on the second pixel electrode.

In an embodiment, the method may further include removing the fourth insulating pattern and the fourth conductive pattern through a second etching process.

In an embodiment, the second etching process may be an anisotropic etching process, and a portion of the fourth insulating pattern and a portion of the fourth conductive pattern may remain after the second etching process.

An electronic device according to an embodiment of the present disclosure includes: a display device including first to third light-emitting layers, and a processor configured to transmit an image data signal and an input control signal to the display device. The display device further includes: a substrate including a first sub-pixel area, a second sub-pixel area, and a third sub-pixel area, a first pixel electrode arranged in the first sub-pixel area on the substrate, a second pixel electrode arranged in the second sub-pixel area on the substrate, a third pixel electrode arranged in the third sub-pixel area on the substrate, a thickness compensation pattern overlapping the third sub-pixel area and including a first insulating pattern, a first conductive pattern, a second insulating pattern, and a second conductive pattern which are sequentially stacked on the third pixel electrode, an anode connection pattern arranged on the third pixel electrode, covering a side surface of the thickness compensation pattern, and contacting the third pixel electrode, the first conductive pattern, and the second conductive pattern, the first light-emitting layer arranged on the first pixel electrode and configured to emit a first light, the second light-emitting layer arranged on the second pixel electrode and configured to emit a second light having a different color from the first light, and the third light-emitting layer arranged on the third pixel electrode and configured to emit a third light having a different color from the first light and the second light.

A display device according to an embodiment of the present disclosure may include first to third pixel electrodes, a first thickness compensation pattern including a first insulating pattern, a first conductive pattern, a second insulating pattern, and a second conductive pattern which are sequentially stacked on the third pixel electrode, and a first anode connection pattern covering a side surface of the first thickness compensation pattern.

Each of the first insulating pattern and the second insulating pattern may include a material having a low light absorption coefficient. Accordingly, a decrease in light efficiency due to the first thickness compensation pattern for controlling the resonance thickness of light may be prevented.

The first anode connection pattern may contact the third pixel electrode, the first conductive pattern, and the second conductive pattern. Accordingly, the first anode connection pattern may electrically connect the third pixel electrode, the first conductive pattern, and the second conductive pattern. That is, even if the first conductive pattern and the second conductive pattern are disconnected in a process of patterning the first thickness compensation pattern, the first anode connection pattern may electrically connect the third pixel electrode, the first conductive pattern, and the second conductive pattern. Accordingly, the reliability of a light-emitting element may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along the line I-I′ of FIG. 1.

FIG. 3 is an enlarged cross-sectional view of the area A of FIG. 2.

FIG. 4 is an enlarged cross-sectional view of the area B of FIG. 2.

FIG. 5 is a cross-sectional view schematically illustrating a light-emitting element included in the display device of FIG. 2.

FIG. 6 is a cross-sectional view illustrating a display device according to an embodiment of the present disclosure.

FIG. 7 is an enlarged cross-sectional view of the area C of FIG. 6.

FIG. 8 is a cross-sectional view illustrating a display device according to an embodiment of the present disclosure.

FIG. 9 is an enlarged cross-sectional view of the area D of FIG. 8.

FIG. 10 is a cross-sectional view illustrating a display device according to an embodiment of the present disclosure.

FIG. 11 is an enlarged cross-sectional view of the area E of FIG. 10.

FIG. 12 is a cross-sectional view illustrating a display device according to an embodiment of the present disclosure.

FIGS. 13, 14, 15, 16, 17, 18, 19, 20, and 21 are cross-sectional views illustrating a method of manufacturing a display device according to an embodiment of the present disclosure.

FIG. 22 is a block diagram of an electronic device according to an embodiment of the present disclosure.

FIG. 23 is a schematic view of an electronic device according to various embodiments.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted. Within the Figures and the text of the disclosure, a reference number indicating a singular form of an element may also be used to reference a plurality of the element.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

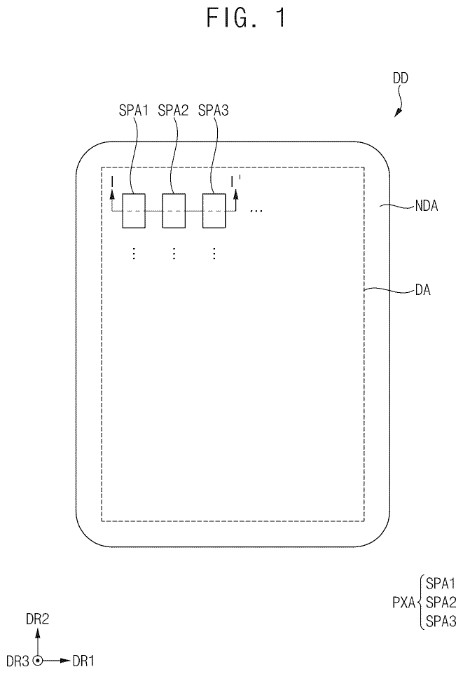

FIG. 1 is a plan view illustrating a display device DD according to an embodiment of the present disclosure.

In this specification, a plane may be defined by a first direction DR1 and a second direction DR2 which intersects the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2. As used herein the “plan view” is a view in the third direction DR3.

Referring to FIG. 1, the display device DD according to an embodiment of the present disclosure may include a display area DA and a non-display area NDA adjacent to each other.

The display area DA may be defined as an area (e.g., a planar area) which generates light or displays an image by controlling the transmittance of light provided from an external light source. The non-display area NDA may be defined as an area which does not display an image. The non-display area NDA may surround at least a portion of the display area DA in a plan view. For example, the non-display area NDA may entirely surround the display area DA in a plan view.

The display area DA may include a plurality of pixel areas PXA. A pixel may be arranged in each of the pixel areas PXA. The pixel may generate light according to a driving signal.

Each of the pixel areas PXA may include a first sub-pixel area SPA1, a second sub-pixel area SPA2, and a third sub-pixel area SPA3 together with each other. Each of the first to third sub-pixel areas SPA1, SPA2, and SPA3 may be an area where light emitted from a light-emitting element is emitted to an outside of the display device DD.

The first to third sub-pixel areas SPA1, SPA2, and SPA3 may emit light of different colors. The first sub-pixel area SPA1 may emit a first light, the second sub-pixel area SPA2 may emit a second light, and the third sub-pixel area SPA3 may emit a third light. In an embodiment, the first light may be red light, the second light may be green light, and the third light may be blue light. However, the present disclosure is not necessarily limited thereto. For example, each of the pixel areas PXA may be combined to emit yellow, cyan, and magenta lights.

Each of the first to third sub-pixel areas SPA1, SPA2, and SPA3 may have any one of a triangular, square, circular, track-shaped, or elliptical planar shape. In an embodiment, each of the first to third sub-pixel areas SPA1, SPA2, and SPA3 may have a rectangular planar shape. However, the present disclosure is not necessarily limited thereto.

In an embodiment, the first to third sub-pixel areas SPA1, SPA2, and SPA3 may have the same area (e.g., planar area or size). However, the present disclosure is not necessarily limited thereto. For example, the first sub-pixel area SPA1 and the second sub-pixel area SPA2 may have the same area (or size), and the third sub-pixel area SPA3 may have a greater area (or size) than the first sub-pixel area SPA1 and the second sub-pixel area SPA2.

The first to third sub-pixel areas SPA1, SPA2, and SPA3 may be repeatedly arranged in a row direction and a column direction in a plan view. For example, the first to third sub-pixel areas SPA1, SPA2, and SPA3 may be repeatedly arranged along the first direction DR1 and the second direction DR2.

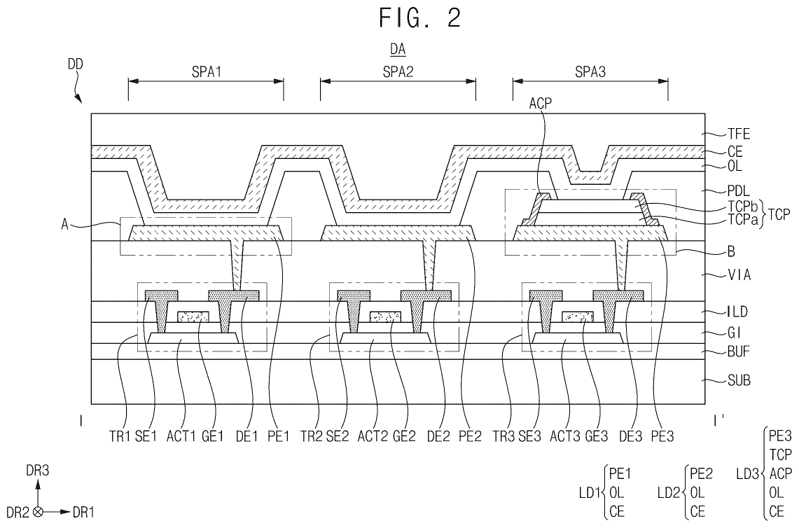

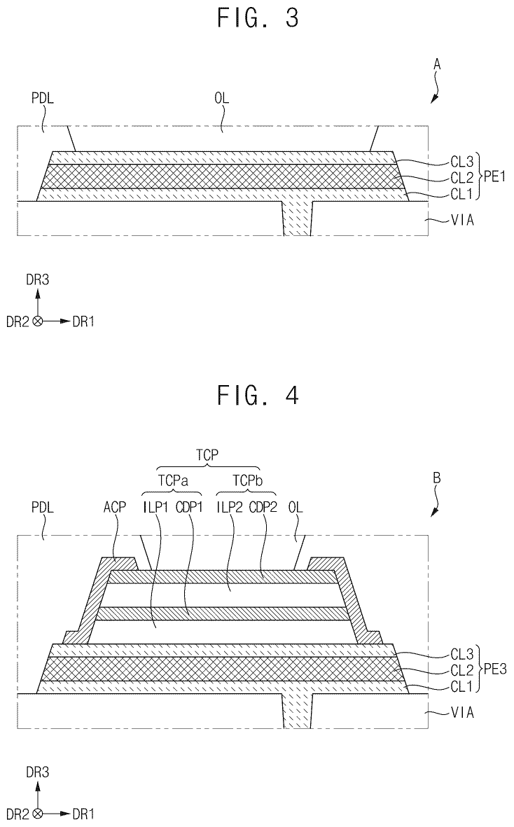

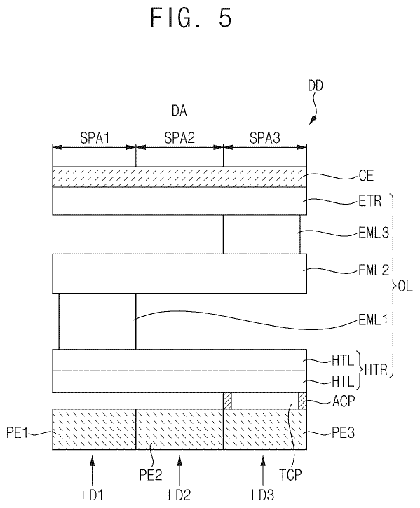

FIG. 2 is a cross-sectional view taken along the line I-I′ of FIG. 1. FIG. 3 is an enlarged cross-sectional view of the area A of FIG. 2. FIG. 4 is an enlarged cross-sectional view of the area B of FIG. 2. FIG. 5 is a cross-sectional view schematically illustrating a light-emitting element included in the display device of FIG. 2.

Referring to FIGS. 2, 3, 4, and 5, the display device DD may include a substrate SUB, a buffer layer BUF, first to third transistors TR1, TR2, and TR3, a gate insulating layer GI, an inter-layer insulating layer ILD, a via-insulating layer VIA, a pixel defining layer PDL, first to third light-emitting elements LD1, LD2, and LD3, and an encapsulation layer TFE.

The first transistor TR1 may include a first active pattern ACT1, a first gate electrode GE1, a first source electrode SE1, and a first drain electrode DE1. The second transistor TR2 may include a second active pattern ACT2, a second gate electrode GE2, a second source electrode SE2, and a second drain electrode DE2. The third transistor TR3 may include a third active pattern ACT3, a third gate electrode GE3, a third source electrode SE3, and a third drain electrode DE3.

The first light-emitting element LD1 may include a first pixel electrode PE1, an organic layer OL, and a common electrode CE. The second light-emitting element LD2 may include a second pixel electrode PE2, the organic layer OL, and the common electrode CE. The third light-emitting element LD3 may include a third pixel electrode PE3, a thickness compensation pattern TCP, an anode connection pattern ACP, the organic layer OL, and the common electrode CE.

The substrate SUB may include a transparent material or an opaque material. The substrate SUB may be formed of (or include) a transparent resin substrate. A polyimide substrate may be an example of the transparent resin substrate. In this case, the polyimide substrate may include a first organic layer, a first barrier layer, a second organic layer, or the like. In an embodiment, the substrate SUB may include a quartz substrate (e.g., a synthetic quartz substrate, a fluorine-doped quartz substrate, or the like), a calcium fluoride substrate, a soda-lime glass substrate, a non-alkali glass substrate, or the like. These may be used alone or in combination with each other.

The buffer layer BUF may be arranged on the substrate SUB. The buffer layer BUF may prevent diffusion of metal atoms or impurities from the substrate SUB to an upper structure. In addition, the buffer layer BUF may serve to improve flatness of a surface of the substrate SUB when the surface of the substrate SUB is not uniform. The buffer layer BUF may include an inorganic insulating material. Examples of the inorganic insulating material which may be used as the buffer layer BUF May include silicon oxide (SiOₓ), silicon nitride (SiNₓ), silicon oxynitride (SiOₓN_{y}), or the like. These may be used alone or in combination with each other. In an embodiment, the buffer layer BUF may be omitted.

The first to third active patterns ACT1, ACT2, and ACT3 of an active pattern layer may be arranged on the buffer layer BUF. The first to third active patterns ACT1, ACT2, and ACT3 may include the same material. Each of the first to third active patterns ACT1, ACT2, and ACT3 may include a silicon semiconductor material, an oxide semiconductor material, an organic semiconductor material, or the like. The first active pattern ACT1 may include a first source area, a first drain area, and a first channel area between the first source area and the first drain area. The second active pattern ACT2 may include a second source area, a second drain area, and a second channel area between the second source area and the second drain area. The third active pattern ACT3 may include a third source area, a third drain area, and a third channel area between the third source area and the third drain area.

The gate insulating layer GI may be arranged on the buffer layer BUF. The gate insulating layer GI may cover the first to third active patterns ACT1, ACT2, and ACT3. The gate insulating layer GI may include an inorganic insulating material. Examples of the inorganic insulating material which may be used as the gate insulating layer GI may include silicon oxide (SiOₓ), silicon nitride (SiNₓ), silicon oxynitride (SiOₓN_{y}), or the like. These may be used alone or in combination with each other.

The first to third gate electrodes GE1, GE2, and GE3 of a gate electrode layer may be arranged on the gate insulating layer GI. The first gate electrode GE1 may overlap the first channel area of the first active pattern ACT1, the second gate electrode GE2 may overlap the second channel area of the second active pattern ACT2, and the third gate electrode GE3 may overlap the third channel area of the third active pattern ACT3. The first to third gate electrodes GE1, GE2, and GE3 may include the same material. Each of the first to third gate electrodes GE1, GE2, and GE3 may include a conductive material such as a metal, an alloy, a conductive metal nitride, a conductive metal oxide, a transparent conductive oxide, or the like. Examples of the conductive material may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The inter-layer insulating layer ILD may be arranged on the gate insulating layer GI. The inter-layer insulating layer ILD may cover the first to third gate electrodes GE1, GE2, and GE3. The inter-layer insulating layer ILD may include an inorganic insulating material. Examples of the inorganic insulating material which may be used as the inter-layer insulating layer ILD may include silicon oxide (SiOₓ), silicon nitride (SiNₓ), silicon oxynitride (SiOₓN_{y}), or the like. These may be used alone or in combination with each other.

The first to third source electrodes SE1, SE2, and SE3 and the first to third drain electrodes DE1, DE2, and DE3 in a transistor electrode layer may be arranged on the inter-layer insulating layer ILD. The first source electrode SE1 may be connected to the first source area of the first active pattern ACT1 through (or at) a contact hole which penetrates the gate insulating layer GI and the inter-layer insulating layer ILD. The first drain electrode DE1 may be connected to the first drain area of the first active pattern ACT1 through a contact hole which penetrates the gate insulating layer GI and the inter-layer insulating layer ILD. The second source electrode SE2 may be connected to the second source area of the second active pattern ACT2 through a contact hole which penetrates the gate insulating layer GI and the inter-layer insulating layer ILD. The second drain electrode DE2 may be connected to the second drain area of the second active pattern ACT2 through a contact hole which penetrates the gate insulating layer GI and the inter-layer insulating layer ILD. The third source electrode SE3 may be connected to the third source area of the third active pattern ACT3 through a contact hole which penetrates the gate insulating layer GI and the inter-layer insulating layer ILD. The third drain electrode DE3 may be connected to the third drain area of the third active pattern ACT3 through a contact hole which penetrates the gate insulating layer GI and the inter-layer insulating layer ILD.

The first to third source electrodes SE1, SE2, and SE3 and the first to third drain electrodes DE1, DE2, and DE3 may include the same material. Each of the first to third source electrodes SE1, SE2, and SE3 and the first to third drain electrodes DE1, DE2, and DE3 may include a conductive material such as a metal, an alloy, a conductive metal nitride, a conductive metal oxide, a transparent conductive oxide, or the like. These may be used alone or in combination with each other.

Accordingly, the first transistor TR1 including the first active pattern ACT1, the first gate electrode GE1, the first source electrode SE1, and the first drain electrode DE1 may be arranged on the substrate SUB. In addition, the second transistor TR2 including the second active pattern ACT2, the second gate electrode GE2, the second source electrode SE2, and the second drain electrode DE2 may be arranged on the substrate SUB. In addition, the third transistor TR3 including the third active pattern ACT3, the third gate electrode GE3, the third source electrode SE3, and the third drain electrode DE3 may be arranged on the substrate SUB.

The via-insulating layer VIA may be arranged on the inter-layer insulating layer ILD. The via-insulating layer VIA may cover the first to third source electrodes SE1, SE2, and SE3 and the first to third drain electrodes DE1, DE2, and DE3. The via-insulating layer VIA may include an organic insulating material. Examples of the organic insulating material which may be used as the via-insulating layer VIA may include polyacryl-based resin, polyimide-based resin, polyamide-based resin, siloxane-based resin, acryl-based resin, epoxy-based resin, or the like. These may be used alone or in combination with each other.

The first to third pixel electrodes PE1, PE2, and PE3 of a pixel electrode layer may be arranged on the via-insulating layer VIA. The first pixel electrode PE1 may overlap the first sub-pixel area SPA1, the second pixel electrode PE2 may overlap the second sub-pixel area SPA2, and the third pixel electrode PE3 may overlap the third sub-pixel area SPA3.

Each of the first to third pixel electrodes PE1, PE2, and PE3 may have a single-layer structure or a multi-layer structure. In an embodiment, each of the first to third pixel electrodes PE1, PE2, and PE3 may have a multi-layer structure including a plurality of conductive layers.

In an embodiment, as illustrated in FIG. 3, the first pixel electrode PE1 may include a first conductive layer CL1, a second conductive layer CL2, and a third conductive layer CL3 which are sequentially stacked on the via-insulating layer VIA. The second pixel electrode PE2 and the third pixel electrode PE3 may have substantially the same structure as the first pixel electrode PE1. That is, each of the second pixel electrode PE2 and the third pixel electrode PE3 may have a structure in which three conductive layers, respectively including the same material as the first to third conductive layers CL1, CL2, and CL3, are stacked.

Each of the first to third conductive layers CL1, CL2, and CL3 may include a conductive material such as a metal, an alloy, a conductive metal nitride, a conductive metal oxide, a transparent conductive oxide, or the like. In an embodiment, the first conductive layer CL1 may include a transparent conductive oxide, the second conductive layer CL2 may include a metal, and the third conductive layer CL3 may include a transparent conductive oxide. In an embodiment, the first conductive layer CL1 and the third conductive layer CL3 may include the same material, but the present disclosure is not necessarily limited thereto.

For example, the first conductive layer CL1 may include indium tin oxide (ITO), the second conductive layer CL2 may include silver (Ag), and the third conductive layer CL3 may include indium tin oxide (ITO). However, the present disclosure is not necessarily limited thereto.

In an embodiment, a thickness (e.g., a length in the third direction DR3) of the second conductive layer CL2 may be greater than a thickness of the first conductive layer CL1 and a thickness of the third conductive layer CL3. Here, the thickness may be taken from a reference surface or reference plane, such as an upper surface of the via-insulating layer VIA.

The thickness compensation pattern TCP may be arranged on the third pixel electrode PE3. The thickness compensation pattern TCP may overlap the third sub-pixel area SPA3. In an embodiment, the thickness compensation pattern TCP may be arranged at an upper surface of the third pixel electrode PE3. A thickness of the thickness compensation pattern TCP may be defined from an upper surface of the third pixel electrode PE3 as a reference surface. A resonance thickness of light emitted from a light-emitting element (e.g., the third light-emitting element LD3) may be controlled by the thickness compensation pattern TCP. The thickness compensation pattern TCP may include a lower thickness compensation pattern TCPa and an upper thickness compensation pattern TCPb sequentially stacked on the third pixel electrode PE3, in a direction away from the third pixel electrode PE3.

As illustrated in FIG. 4, the lower thickness compensation pattern TCPa may include a first insulating pattern ILP1 and a first conductive pattern CDP1 on the first insulating pattern ILP1, and the upper thickness compensation pattern TCPb may include a second insulating pattern ILP2 and a second conductive pattern CDP2 on the second insulating pattern ILP2. That is, the thickness compensation pattern TCP may include the first insulating pattern ILP1, the first conductive pattern CDP1, the second insulating pattern ILP2, and the second conductive pattern CDP2 sequentially stacked on the third pixel electrode PE3.

Each of the first insulating pattern ILP1 and the second insulating pattern ILP2 may include a material having a low light absorption coefficient. For example, each of the first insulating pattern ILP1 and the second insulating pattern ILP2 may include silicon oxide (SiOₓ), silicon nitride (SiNₓ), or the like. In an embodiment, each of the first insulating pattern ILP1 and the second insulating pattern ILP2 may include silicon dioxide (SiO₂).

In an embodiment, the first insulating pattern ILP1 and the second insulating pattern ILP2 may include the same material. However, the present disclosure is not necessarily limited thereto, and the first insulating pattern ILP1 and the second insulating pattern ILP2 may include different materials from each other.

Each of the first conductive pattern CDP1 and the second conductive pattern CDP2 may include a transparent conductive oxide. For example, each of the first conductive pattern CDP1 and the second conductive pattern CDP2 may include indium tin oxide (ITO), indium zinc oxide (IZO), or the like. In an embodiment, each of the first conductive pattern CDP1 and the second conductive pattern CDP2 may include indium tin oxide (ITO).

In an embodiment, the first conductive pattern CDP1 and the second conductive pattern CDP2 may include the same material. However, the present disclosure is not necessarily limited thereto, and the first conductive pattern CDP1 and the second conductive pattern CDP2 may include different materials from each other.

In an embodiment, a thickness of the first insulating pattern ILP1 and a thickness of the second insulating pattern ILP2 may each be greater than a thickness of the first conductive pattern CDP1 and a thickness of the second conductive pattern CDP2. For example, the thickness of each of the first insulating pattern ILP1 and the second insulating pattern ILP2 may be about 300 angstroms (Å), and the thickness of each of the first conductive pattern CDP1 and the second conductive pattern CDP2 may be about 70 Å, but the present disclosure is not necessarily limited thereto. In an embodiment, side surfaces of the first conductive pattern CDP1, the first insulating pattern ILP1, the second conductive pattern CDP2 and the second insulating pattern ILP2 may be aligned, such as to be coplanar with each other.

The anode connection pattern ACP may be arranged on the third pixel electrode PE3. For example, the anode connection pattern ACP may be arranged on the upper surface of the third pixel electrode PE3 and may contact an edge of the third pixel electrode PE3. In an embodiment, the anode connection pattern ACP may be spaced apart from a central portion of the third pixel electrode PE3 in a plan view. That is, the anode connection pattern ACP may not overlap the central portion of the third pixel electrode PE3 in a plan view. Ends of the anode connection pattern ACP may also be spaced apart from ends of the third pixel electrode PE3.

The anode connection pattern ACP may extend from an upper surface of the third pixel electrode PE3 and along an outer side surface of the thickness compensation pattern TCP to cover a side surface of the thickness compensation pattern TCP. In an embodiment, the anode connection pattern ACP may entirely surround the thickness compensation pattern TCP in a plan view. The anode connection pattern ACP may contact a side surface of the first insulating pattern ILP), a side surface of the first conductive pattern CDP1, a side surface of the second insulating pattern ILP2, and a side surface of the second conductive pattern CDP2. In addition, the anode connection pattern ACP may contact an upper surface of the thickness compensation pattern TCP. Specifically, the anode connection pattern ACP may contact an edge of an upper surface of the second conductive pattern CDP2. As being in contact, elements may form an interface therebetween.

The anode connection pattern ACP may contact the third pixel electrode PE3, the first conductive pattern CDP1, and the second conductive pattern CDP2. The anode connection pattern ACP may electrically connect the third pixel electrode PE3, the first conductive pattern CDP1, and the second conductive pattern CDP2 to each other. The anode connection pattern ACP may define a compensation pattern opening at which the uppermost layer of the thickness compensation pattern TCP is exposed to outside the anode connection pattern ACP. In an embodiment, the pixel electrode structure together with structures of the thickness compensation pattern TCP and the anode connection pattern ACP may be considered a pixel electrode of a light emitting element, without being limited thereto.

The anode connection pattern ACP may include a conductive material. For example, the anode connection pattern ACP may include a metal. In an embodiment, the anode connection pattern ACP may include titanium (Ti), but the present disclosure is not necessarily limited thereto.

The pixel defining layer PDL may be arranged on the via-insulating layer VIA. The pixel defining layer PDL may cover an edge of the first pixel electrode PE1, an edge of the second pixel electrode PE2, and an edge of the thickness compensation pattern TCP. In addition, the pixel defining layer PDL may cover the anode connection pattern ACP as uppermost layers of the various pixel electrodes. The pixel defining layer PDL may expose a portion of an upper surface of each of the first pixel electrode PE1, the second pixel electrode PE2, and the thickness compensation pattern TCP to outside the pixel defining layer PDL. The pixel defining layer PDL may define a pixel opening through which the various pixel electrodes are exposed to outside the pixel defining layer PDL.

The pixel defining layer PDL may include an organic insulating material and/or an inorganic insulating material. In an embodiment, the pixel defining layer PDL may further include a light blocking material having a black color. For example, the pixel defining layer PDL may further include a black pigment, a black dye, carbon black, or the like. These may be used alone or in combination with each other.

The organic layer OL of the various light emitting elements may be arranged on the pixel defining layer PDL, the first pixel electrode PE1, the second pixel electrode PE2, and the third pixel electrode PE3. The organic layer OL may be arranged on the thickness compensation pattern TCP in the third sub-pixel area SPA3. The organic layer OL may continuously extend across the first sub-pixel area SPA1, the second sub-pixel area SPA2, and the third sub-pixel area SPA3. In this case, as illustrated in FIG. 5, a first light-emitting layer EML1 and a third light-emitting layer EML3 included in the organic layer OL may be individually arranged in the first sub-pixel area SPA1 and the third sub-pixel area SPA3, respectively.

Referring to FIG. 5, the first light-emitting layer EML1 and the third light-emitting layer EML3 as thickness portions of the organic layer OL may be spaced apart from each other in a direction along the organic layer OL, while other thickness portions of the organic layer are continuously extended over various sub-pixel areas.

The organic layer OL may include a hole transport area HTR, the first light-emitting layer EML1, a second light-emitting layer EML2, the third light-emitting layer EML3, and an electron transport area ETR each as a thickness portion of the organic layer OL. The first light-emitting layer EML1 may be included in the first light-emitting element LD1, the second light-emitting layer EML2 may be included in the second light-emitting element LD2, and the third light-emitting layer EML3 may be included in the third light-emitting element LD3.

The first light-emitting layer EML1 may emit a first light, the second light-emitting layer EML2 may emit a second light, and the third light-emitting layer EML3 may emit a third light. For example, the first light may be red light, the second light may be green light, and the third light may be blue light. However, the present disclosure is not necessarily limited thereto.

The thickness compensation pattern TCP may be arranged on an upper surface of the third pixel electrode PE3. The resonance thickness of light may be controlled by the thickness compensation pattern TCP. That is, the thickness compensation pattern TCP may form an optimal resonance thickness of light. Here, the resonance thickness of light may be defined as a thickness at which a resonance phenomenon of light occurs. The resonance thickness may vary depending on the wavelength of light. In an embodiment, the thickness compensation pattern TCP may form an optimal resonance thickness of the third light emitted from the third light-emitting layer EML3.

The first pixel electrode PE1 may be defined as a first anode, the second pixel electrode PE2 may be defined as a second anode, and the third pixel electrode PE3 together with the thickness compensation pattern TCP may be defined as a third anode. A total thickness of the third anode may be controlled by the thickness compensation pattern TCP. The total thickness of the third anode may be different from a total thickness of the first anode and a total thickness of the second anode. For example, the total thickness of the third anode may be greater than the total thickness of the first anode and the thickness of the second anode.

The hole transport area HTR may be commonly arranged on the first to third pixel electrodes PE1, PE2, and PE3 and the thickness compensation pattern TCP. The hole transport area HTR may overlap the first to third sub-pixel areas SPA1, SPA2, and SPA3. The hole transport area HTR may include a hole injection layer HIL and a hole transport layer HTL.

The first light-emitting layer EML1 may be arranged on the hole transport layer HTL. The first light-emitting layer EML1 may overlap the first sub-pixel area SPA1. The first light-emitting layer EML1 may include an organic material which emits the first light. In an embodiment, the first light-emitting layer EML1 may include a first auxiliary layer. A thickness of the first auxiliary layer may be adjusted to enhance resonance of the first light emitted from the first light-emitting layer EML1. For example, the first auxiliary layer may include an amine-based organic compound, but the present disclosure is not necessarily limited thereto. In an embodiment, the first light-emitting layer EML1 may not be arranged on the second sub-pixel area SPA2 and the third sub-pixel area SPA3, such as to be adjacent thereto and/or non-overlapping therewith.

The second light-emitting layer EML2 may be arranged on the first light-emitting layer EML1. The second light-emitting layer EML2 may be continuous to overlap each of the first to third sub-pixel areas SPA1, SPA2, and SPA3. That is, the second light-emitting layer EML2 may be commonly arranged in the display area DA. The second light-emitting layer EML2 may include an organic material which emits the second light.

The third light-emitting layer EML3 may be arranged on the second light-emitting layer EML2. The third light-emitting layer EML3 may overlap the third sub-pixel area SPA3. The third light-emitting layer EML3 may include an organic material which emits the third light. In an embodiment, the third light-emitting layer EML3 may include a second auxiliary layer. A thickness of the second auxiliary layer may be adjusted to enhance resonance of the third light emitted from the third light-emitting layer EML3. For example, the second auxiliary layer may include an amine-based organic compound, but the present disclosure is not necessarily limited thereto. In an embodiment, the third light-emitting layer EML3 may not be arranged on the first sub-pixel area SPA1 and the second sub-pixel area SPA2, such as to be adjacent thereto and/or non-overlapping therewith.

The electron transport area ETR may be commonly arranged on the first light-emitting layer EML1, the second light-emitting layer EML2, and the third light-emitting layer EML3. The electron transport area ETR may overlap each of the first to third sub-pixel areas SPA1, SPA2, and SPA3. The electron transport area ETR may include at least one of an electron injection layer and an electron transport layer.

In a method of providing the display device DD, a fine metal mask (FMM) may be used twice to form the first to third light-emitting layers EML1, EML2, and EML3. Accordingly, the manufacturing process of the display device DD may be simplified compared to when the light-emitting layer is individually formed in each of the first to third sub-pixel areas SPA1, SPA2, and SPA3. That is, since the display device DD includes the thickness compensation pattern TCP, a separate process of forming an organic thickness compensation pattern using the fine metal mask may be omitted.

As illustrated in FIG. 2, the common electrode CE may be arranged on the organic layer OL. The common electrode CE may continuously extend across the first to third sub-pixel areas SPA1, SPA2, and SPA3. The common electrode CE may be arranged along the profile of the organic layer OL (e.g., a cross-sectional shape) to have a substantially uniform thickness. The common electrode CE may include a conductive material such as a metal, an alloy, a conductive metal nitride, a conductive metal oxide, a transparent conductive oxide, or the like. These may be used alone or in combination with each other. For example, the common electrode CE may function as a cathode.

Accordingly, the first light-emitting element LD1 including the first pixel electrode PE1, the organic layer OL, and the common electrode CE may be arranged on the via-insulating layer VIA. The second light-emitting element LD2 including the second pixel electrode PE2, the organic layer OL, and the common electrode CE may be arranged on the via-insulating layer VIA. The third light-emitting element LD3 including the third pixel electrode PE3, the thickness compensation pattern TCP, the anode connection pattern ACP, the organic layer OL, and the common electrode CE may be arranged on the via-insulating layer VIA.

The encapsulation layer TFE may be arranged on the common electrode CE. The encapsulation layer TFE prevents impurities, moisture, or the like from penetrating into the first to third light-emitting elements LD1, LD2, and LD3 from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), or the like. These may be used alone or in combination with each other. For example, the organic encapsulation layer may include a polymer cured material such as polyacrylate.

According to the embodiments of the present disclosure, since the display device DD includes the thickness compensation pattern TCP, a process of forming an organic thickness compensation pattern using the fine metal mask may be omitted, and the display device DD having a high resolution may be reliably manufactured. In other words, the display device DD may implement high resolution (e.g., greater than or equal to about 1500 pixels per inch (ppi)).

According to the embodiments of the present disclosure, the thickness compensation pattern TCP may include the first insulating pattern ILP1 and the second insulating pattern ILP2 which have a low light absorption coefficient, and may include the first conductive pattern CDP1 and the second conductive pattern CDP2 which include a transparent conductive oxide. As a total thickness of the thickness compensation pattern TCP includes the first insulating pattern ILP1 and the second insulating pattern ILP2 having a relatively low light absorption coefficient (e.g., lower than a light absorption coefficient of the conductive pattern), a decrease in light efficiency due to the thickness compensation pattern TCP for controlling the resonance thickness of light may be prevented. In other words, compared to when a total thickness of the thickness compensation pattern TCP includes only a transparent conductive oxide, the thickness compensation pattern TCP of one or more embodiment of the present disclosure including the first insulating pattern ILP1 and the second insulating pattern ILP2 may absorb relatively less light, and thus the light efficiency may be improved.

According to the embodiments of the present disclosure, the anode connection pattern ACP may contact the pixel electrode (e.g., the third pixel electrode PE3) and the conductive patterns CDP1 and CDP2 as thickness portions included in the total thickness of the thickness compensation pattern TCP. Accordingly, the anode connection pattern ACP may electrically connect the underlying pixel electrode, the first conductive pattern CDP1, and the second conductive pattern CDP2 to each other. That is, even if the first conductive pattern CDP1 and the second conductive pattern CDP2 are disconnected in the process of patterning the thickness compensation pattern TCP, the anode connection pattern ACP contacting each of the pixel electrode, the first conductive pattern CDP1, and the second conductive pattern CDP2 may electrically connect the pixel electrode, the first conductive pattern CDP1, and the second conductive pattern CDP2 to each other. Accordingly, the reliability of the light-emitting element (e.g., the third light-emitting element LD3) may be improved.

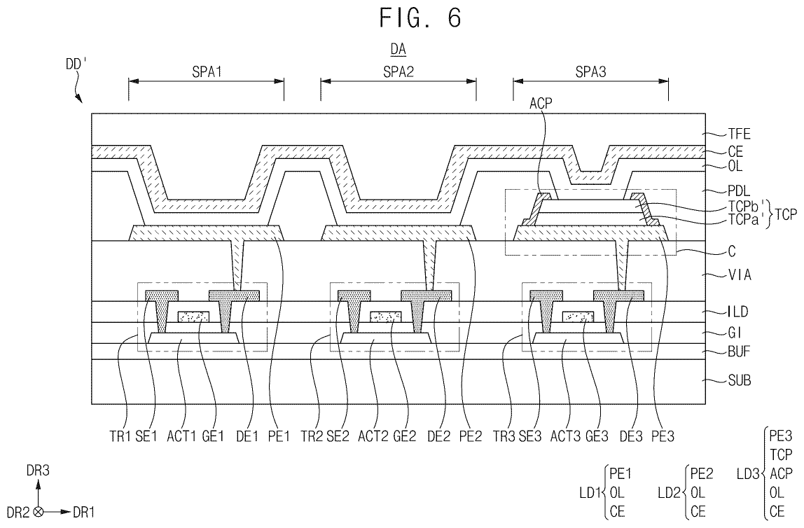

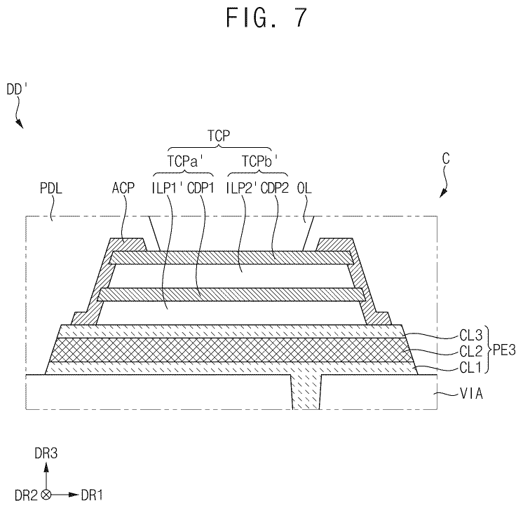

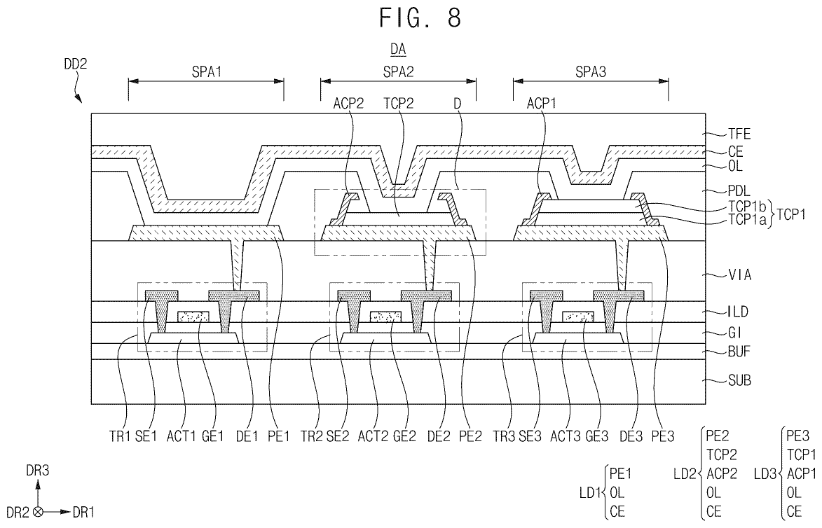

FIG. 6 is a cross-sectional view illustrating a display device DD′ according to an embodiment of the present disclosure. FIG. 7 is an enlarged cross-sectional view of the area C of FIG. 6.

Referring to FIGS. 6 and 7, a display device DD′ according to an embodiment of the present disclosure may include a substrate SUB, a buffer layer BUF, first to third transistors TR1, TR2, and TR3, a gate insulating layer GI, an inter-layer insulating layer ILD, a via-insulating layer VIA, a pixel defining layer PDL, first to third light-emitting elements LD1, LD2, and LD3, and an encapsulation layer TFE. The third light-emitting element LD3 may include a third pixel electrode PE3, a thickness compensation pattern TCP, an anode connection pattern ACP, an organic layer OL, and a common electrode CE. The thickness compensation pattern TCP may include a lower thickness compensation pattern TCPa′ and an upper thickness compensation pattern TCPb′. The lower thickness compensation pattern TCPa′ may include a first insulating pattern ILP1′ and a first conductive pattern CDP1, and the upper thickness compensation pattern TCPb′ may include a second insulating pattern ILP2′ and a second conductive pattern CDP2.

The display device DD′ may be substantially the same as the display device DD described above with reference to FIGS. 1 to 5, except that a side surface of the first conductive pattern CDP1 protrudes more than a side surface of the first insulating pattern ILP1′, and a side surface of the second conductive pattern CDP2 protrudes more than a side surface of the second insulating pattern ILP2′. That is, the conductive patterns may protrude further than side (or end) surfaces of the insulating patterns to define a protruded portion (e.g., a tip) of the respective conductive patterns. Hereinafter, redundant descriptions of the display device DD described above with reference to FIGS. 1 to 5 may be omitted or may be summarized.

The thickness compensation pattern TCP may be arranged on the pixel electrode (e.g., the third pixel electrode PE3). The thickness compensation pattern TCP may overlap the third sub-pixel area SPA3. The resonance thickness of light emitted from the light-emitting element (e.g., the third light-emitting element LD3) may be controlled by the thickness compensation pattern TCP. The thickness compensation pattern TCP may include the first insulating pattern ILP1′, the first conductive pattern CDP1, the second insulating pattern ILP2′, and the second conductive pattern CDP2 which are sequentially stacked on the third pixel electrode PE3.

Each of the first insulating pattern ILP1′ and the second insulating pattern ILP2′ may include a material having a low light absorption coefficient. For example, each of the first insulating pattern ILP1′ and the second insulating pattern ILP2′ may include silicon oxide (SiOₓ), silicon nitride (SiNₓ), or the like.

Each of the first conductive pattern CDP1 and the second conductive pattern CDP2 may include a transparent conductive oxide. For example, each of the first conductive pattern CDP1 and the second conductive pattern CDP2 may include indium tin oxide (ITO), indium zinc oxide (IZO), or the like.

In an embodiment, as illustrated in FIG. 7, the side surface of the first conductive pattern CDP1 may protrude more in a direction away from a center of the thickness compensation pattern TCP than the side surface of the first insulating pattern ILP1′. The side surface of the second conductive pattern CDP2 may protrude more in the direction away from the center of the thickness compensation pattern TCP than the side surface of the second insulating pattern ILP2′. In this case, in a process of patterning the thickness compensation pattern TCP, the first insulating pattern ILP1′ and the second insulating pattern ILP2′ may be additionally (e.g., relatively more) etched. Accordingly, the side surface of the first insulating pattern ILP1′ and the side surface of the second insulating pattern ILP2′ may have a recessed structure toward the center of the thickness compensation pattern TCP.

The anode connection pattern ACP may cover the side surface of the thickness compensation pattern TCP. The anode connection pattern ACP may contact the side surface of the first insulating pattern ILP1′, the side surface of the first conductive pattern CDP1, the side surface of the second insulating pattern ILP2′, and the side surface of the second conductive pattern CDP2. In addition, the anode connection pattern ACP may contact an upper surface of the thickness compensation pattern TCP.

In an embodiment, the anode connection pattern ACP may contact a lower surface of the first conductive pattern CDP1 and a lower surface of the second conductive pattern CDP2, at the protruded portions thereof. That is, as the side surface of the first insulating pattern ILP1′ has a recessed structure, a portion of the lower surface of the first conductive pattern CDP1 may not be covered by the first insulating pattern ILP1′. In addition, as the side surface of the second insulating pattern ILP2′ has a recessed structure, a portion of the lower surface of the second conductive pattern CDP2 may not be covered by the second insulating pattern ILP2′. In this case, the anode connection pattern ACP may contact the portion of the lower surface of the first conductive pattern CDP1 and the portion of the lower surface of the second conductive pattern CDP2 which protrude further than side surfaces of the insulating patterns. Accordingly, a contact area (e.g., a planar contact area) between the anode connection pattern ACP and the first conductive pattern CDP1 and a contact area between the anode connection pattern ACP and the second conductive pattern CDP2 may be relatively increased since contact areas are defined not only at an upper surface of the thickness compensation pattern and along side surfaces, but also along a lower surface of the conductive patterns. The anode connection pattern ACP may more stably (electrically) contact the first conductive pattern CDP1 and the second conductive pattern CDP2.

Referring to FIG. 7, for example, within the first anode (like PE3, TCP1 and ACP1 together), the first conductive pattern CDP1 protrudes further than a side surface of the first insulating pattern ILP1 to define a protruded portion of the first conductive pattern CDP1, and the second conductive pattern CDP2 protrudes further than a side surface of the second insulating pattern ILP2 to define a protruded portion of the second conductive pattern CDP2.

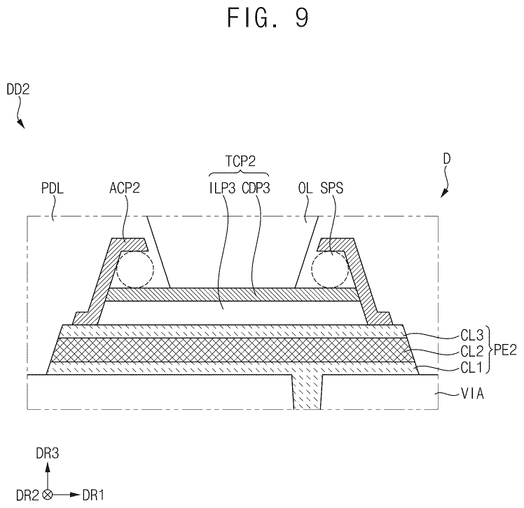

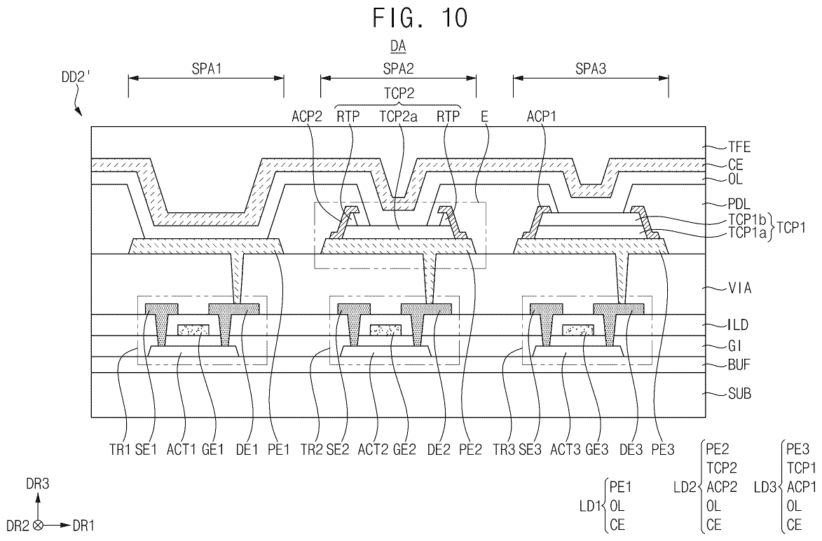

FIG. 8 is a cross-sectional view illustrating a display device DD2 according to an embodiment of the present disclosure. FIG. 9 is an enlarged cross-sectional view of the area D of FIG. 8.

Referring to FIGS. 8 and 9, a display device DD2 according to an embodiment of the present disclosure may include a substrate SUB, a buffer layer BUF, first to third transistors TR1, TR2, and TR3, a gate insulating layer GI, an inter-layer insulating layer ILD, a via-insulating layer VIA, a pixel defining layer PDL, first to third light-emitting elements LD1, LD2, and LD3, and an encapsulation layer TFE. The third light-emitting element LD3 may include a third pixel electrode PE3, a first thickness compensation pattern TCP1, a first anode connection pattern ACP1, an organic layer OL, and a common electrode CE. The second light-emitting element LD2 may include a second pixel electrode PE2, a second thickness compensation pattern TCP2, a second anode connection pattern ACP2, the organic layer OL, and the common electrode CE.

The display device DD2 may be substantially the same as the display device DD described above with reference to FIGS. 1 to 5, except that the display device DD2 further includes the second thickness compensation pattern TCP2 overlapping the second sub-pixel area SPA2 and arranged on the second pixel electrode PE2 and the second anode connection pattern ACP2 covering the second thickness compensation pattern TCP2. Hereinafter, redundant descriptions of the display device DD described above with reference to FIGS. 1 to 5 may be omitted or may be summarized.

The first thickness compensation pattern TCP1 may be arranged on the third pixel electrode PE3. The first thickness compensation pattern TCP1 may overlap the third sub-pixel area SPA3. The resonance thickness of light emitted from the third light-emitting element LD3 may be controlled by the first thickness compensation pattern TCP1. The first thickness compensation pattern TCP1 may include a first lower thickness compensation pattern TCPa and a first upper thickness compensation pattern TCPb which are sequentially stacked on the third pixel electrode PE3. The first thickness compensation pattern TCP1 may have substantially the same structure as the thickness compensation pattern TCP of FIG. 4.

The second thickness compensation pattern TCP2 may be arranged on the second pixel electrode PE2. The second thickness compensation pattern TCP2 may overlap the second sub-pixel area SPA2. In an embodiment, the second thickness compensation pattern TCP2 may be arranged at an upper surface of the second pixel electrode PE2. The resonance thickness of light emitted from the second light-emitting element LD2 may be controlled by the second thickness compensation pattern TCP2.

As illustrated in FIG. 9, the second thickness compensation pattern TCP2 may include a third insulating pattern ILP3 and a third conductive pattern CDP3 which are sequentially stacked on the second pixel electrode PE2.

The third insulating pattern ILP3 may include a material having a low light absorption coefficient. For example, the third insulating pattern ILP3 may include silicon oxide (SiOₓ), silicon nitride (SiNₓ), or the like. The third insulating pattern ILP3 and the first insulating pattern ILP1 of FIG. 4 may include the same material and may be formed through the same process. In an embodiment, a thickness of the third insulating pattern ILP3 may be the same as the thickness of the first insulating pattern ILP1 of FIG. 4. In an embodiment, the third insulating pattern ILP3 and the first insulating pattern ILP1 may be in a same layer among layers on the substrate SUB. For example, the sub-pixel areas may further include an insulating layer and a conductive layer. Here, the insulating layer may define both the first insulating pattern ILP1 of the first anode and the third insulating pattern ILP3 of the second anode, The conductive layer may define both the first conductive pattern CDP1 of the first anode and the third conductive pattern CDP3 of the second anode.

As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The third conductive pattern CDP3 may include a transparent conductive oxide. For example, the third conductive pattern CDP3 may include indium tin oxide (ITO), indium zinc oxide (IZO), or the like. The third conductive pattern CDP3 and the first conductive pattern CDP1 of FIG. 4 may include the same material and may be formed through the same process (e.g., may be in a same layer as each other). In an embodiment, a thickness of the third conductive pattern CDP3 may be the same as the thickness of the first conductive pattern CDP1 of FIG. 4.

In an embodiment, the thickness of the third insulating pattern ILP3 may be greater than the thickness of the third conductive pattern CDP3. For example, the thickness of the third insulating pattern ILP3 may be about 300 Å, and the thickness of the third conductive pattern CDP3 may be about 70 Å, but the present disclosure is not necessarily limited thereto.

The first anode connection pattern ACP1 may be arranged on the third pixel electrode PE3. The first anode connection pattern ACP1 may cover a side surface of the first thickness compensation pattern TCP1. The first anode connection pattern ACP1 may electrically connect the third pixel electrode PE3 and the conductive pattern included in the first thickness compensation pattern TCP1 to each other. Accordingly, the reliability of the third light-emitting element LD3 and electrical connections therein may be improved. The first anode connection pattern ACP1 may have substantially the same structure as the anode connection pattern ACP of FIG. 4.

In an embodiment, the second anode connection pattern ACP2 may be arranged on the second pixel electrode PE2. For example, the second anode connection pattern ACP2 may be arranged at the upper surface of the second pixel electrode PE2 and may contact an edge of the second pixel electrode PE2. The second anode connection pattern ACP2 may be spaced apart from a central portion of the second pixel electrode PE2 in a plan view. That is, the second anode connection pattern ACP2 may not overlap the central portion of the second pixel electrode PE2 in a plan view.

The second anode connection pattern ACP2 may cover a side surface of the second thickness compensation pattern TCP2. In an embodiment, the second anode connection pattern ACP2 may entirely surround the second thickness compensation pattern TCP2 in a plan view. The second anode connection pattern ACP2 may contact a side surface of the third insulating pattern ILP3 and a side surface of the third conductive pattern CDP3.

In an embodiment, the second anode connection pattern ACP2 may be spaced apart from an upper surface of the second thickness compensation pattern TCP2, such as by a gap. That is, a spaced space SPS as a space (or empty space) may be formed (or provided) between the second anode connection pattern ACP2 and the second thickness compensation pattern TCP2. The third insulating pattern ILP3 and the third conductive pattern CDP3 may define a lower thickness portion of the second thickness compensation pattern TCP2, while an upper thickness portion is defined at the space. That is, the third conductive pattern CDP3 is exposed to outside the second anode connection pattern ACP2.

In a method of providing the display device DD2, the spaced space SPS may be formed by removing material of an insulating pattern and material of a conductive pattern which are positioned on the third conductive pattern CDP3 in a process of patterning material layers to form the second thickness compensation pattern TCP2. In an embodiment, the insulating pattern and the conductive pattern positioned on the third conductive pattern CDP3 may be removed by an isotropic etching process in the process of patterning the second thickness compensation pattern TCP2.

The second anode connection pattern ACP2 may contact the second pixel electrode PE2 and the third conductive pattern CDP3. That is, the second anode connection pattern ACP2 may electrically connect the second pixel electrode PE2 and the third conductive pattern CDP3 to each other. Accordingly, the reliability of the second light-emitting element LD2 may be improved.

The first pixel electrode PE1 may be defined as a first anode, the second pixel electrode PE2 and the second thickness compensation pattern TCP2 may be defined as a second anode, and the third pixel electrode PE3 and the first thickness compensation pattern TCP1 may be defined as a third anode. A thickness of the second anode may be controlled by the second thickness compensation pattern TCP2, and a thickness of the third anode may be controlled by the first thickness compensation pattern TCP1. A total thickness of the first anode, the total thickness of the second anode, and the total thickness of the third anode may be different from each other. For example, the total thickness of the third anode may be greater than the total thickness of the second anode, and the total thickness of the second anode may be greater than the total thickness of the first anode.

FIG. 10 is a cross-sectional view illustrating a display device according to an embodiment of the present disclosure. FIG. 11 is an enlarged cross-sectional view of the area E of FIG. 10.

Referring to FIGS. 10 and 11, a display device DD2′ according to an embodiment of the present disclosure may include a substrate SUB, a buffer layer BUF, first to third transistors TR1, TR2, and TR3, a gate insulating layer GI, an inter-layer insulating layer ILD, a via-insulating layer VIA, a pixel defining layer PDL, first to third light-emitting elements LD1, LD2, and LD3, and an encapsulation layer TFE. The second light-emitting element LD2 may include a second pixel electrode PE2, a second thickness compensation pattern TCP2, a second anode connection pattern ACP2, an organic layer OL, and a common electrode CE. The second thickness compensation pattern TCP2 may include a second lower thickness compensation pattern TCP2a and a residual pattern RTP, and the second lower thickness compensation pattern TCP2a may include a third insulating pattern ILP3 and a third conductive pattern CDP3.

The display device DD2′ may be substantially the same as the display device DD2 described above with reference to FIGS. 8 and 9, except that the second thickness compensation pattern TCP2 further includes the residual pattern RTP. Hereinafter, redundant descriptions of the display device DD2 described above with reference to FIGS. 8 and 9 may be omitted or may be summarized.

The second thickness compensation pattern TCP2 may be arranged on the second pixel electrode PE2. The second thickness compensation pattern TCP2 may overlap the second sub-pixel area SPA2. The second thickness compensation pattern TCP2 may include the second lower thickness compensation pattern TCP2a and the residual pattern RTP at lower and upper thickness portions of the second thickness compensation portion TCP2. The residual pattern RTP may overlap an edge of the second lower thickness compensation pattern TCP2a, while exposing an upper surface of the second lower thickness compensation pattern TCP2a to outside the residual pattern RTP. The residual pattern RTP may include a residual insulating pattern RIP and a residual conductive pattern RCP. A surface of the second thickness compensation portion TCP2 which exposed outside the residual pattern RTP, may be further exposed to outside the second anode by the second anode connection pattern ACP2. That is, the residual pattern RTP may include a residual insulating pattern RIP and a residual conductive pattern RCP in order from the third conductive pattern CDP3, where each of the residual insulating pattern RIP and the residual conductive pattern RCP overlaps an edge of the third conductive pattern CDP3.

As illustrated in FIG. 11, the second thickness compensation pattern TCP2 may include the third insulating pattern ILP3, the third conductive pattern CDP3, the residual insulating pattern RIP, and the residual conductive pattern RCP which are sequentially stacked on the second pixel electrode PE2.

The residual insulating pattern RIP may be arranged on the third conductive pattern CDP3. For example, the residual insulating pattern RIP may overlap an edge of the third conductive pattern CDP3. The residual insulating pattern RIP and the second insulating pattern ILP2 of FIG. 4 may include the same material, such as to be in a same layer as each other. In an embodiment, a thickness of the residual insulating pattern RIP may be the same as the thickness of the second insulating pattern ILP2 of FIG. 4.

The residual conductive pattern RCP may be arranged on the residual insulating pattern RIP. The residual conductive pattern RCP and the second conductive pattern CDP2 of FIG. 4 may include the same material, such as to be in a same layer as each other. In an embodiment, a thickness of the residual conductive pattern RCP may be the same as the thickness of the second conductive pattern CDP2 of FIG. 4.

The second anode connection pattern ACP2 may cover a side surface of the second thickness compensation pattern TCP2. The second anode connection pattern ACP2 may contact a side surface of the third insulating pattern ILP3, a side surface of the third conductive pattern CDP3, a side surface of the residual insulating pattern RIP, and a side surface of the residual conductive pattern RCP. In an embodiment, the second anode connection pattern ACP2 may overlap an entirety of the residual pattern RTP in a plan view. That is, the second anode connection pattern ACP2 may overlap an entirety of the residual insulating pattern RIP and an entirety of the residual conductive pattern RCP in a plan view.

In an embodiment of providing the display device DD2′, the residual pattern RTP may be formed by removing material of an insulating pattern and material of a conductive pattern positioned on the third conductive pattern CDP3 in a process of patterning material layers forming the second thickness compensation pattern TCP2. In an embodiment, the insulating pattern and the conductive pattern positioned on the third conductive pattern CDP3 may be removed by an anisotropic etching process in the process of patterning the second thickness compensation pattern TCP2. Accordingly, a portion of the insulating pattern overlapping the second anode connection pattern ACP2 in a plan view may remain after the etching process, and the residual insulating pattern RIP may be formed. In addition, a portion of the conductive pattern overlapping the second anode connection pattern ACP2 in a plan view may remain after the etching process, and the residual conductive pattern RCP may be formed.

FIG. 12 is a cross-sectional view illustrating a display device DD3 according to an embodiment of the present disclosure.

Referring to FIG. 12, a display device DD3 according to an embodiment of the present disclosure may include a substrate SUB, a buffer layer BUF, first to third transistors TR1, TR2, and TR3, a gate insulating layer GI, an inter-layer insulating layer ILD, a via-insulating layer VIA, a pixel defining layer PDL, first to third light-emitting elements LD1, LD2, and LD3, and an encapsulation layer TFE. The third light-emitting element LD3 may include a third pixel electrode PE3, a first thickness compensation pattern TCP1, a first anode connection pattern ACP1, an organic layer OL, and a common electrode CE. The second light-emitting element LD2 may include a second pixel electrode PE2, a second thickness compensation pattern TCP2, a second anode connection pattern ACP2, the organic layer OL, and the common electrode CE. The first light-emitting element LD1 may include a first pixel electrode PE1, a third thickness compensation pattern TCP3, a third anode connection pattern ACP3, the organic layer OL, and the common electrode CE.

The display device DD3 may be substantially the same as the display device DD2 described above with reference to FIGS. 8 and 9, except that the display device DD3 further includes the third thickness compensation pattern TCP3 overlapping the first sub-pixel area SPA1 and arranged on the first pixel electrode PE1 and the third anode connection pattern ACP3 covering the third thickness compensation pattern TCP3. Hereinafter, redundant descriptions of the display device DD2 described above with reference to FIGS. 8 and 9 may be omitted or may be summarized.

The first thickness compensation pattern TCP1 may be arranged in the third sub-pixel area SPA3 on the third pixel electrode PE3. The resonance thickness of light emitted from the third light-emitting element LD3 may be controlled by the first thickness compensation pattern TCP1. The first thickness compensation pattern TCP1 may have substantially the same structure as the thickness compensation pattern TCP of FIG. 4.

The second thickness compensation pattern TCP2 may be arranged in the second sub-pixel area SPA2 on the second pixel electrode PE2. The resonance thickness of light emitted from the second light-emitting element LD2 may be controlled by the second thickness compensation pattern TCP2. The second thickness compensation pattern TCP2 may have substantially the same structure as the second thickness compensation pattern TCP2 of FIG. 9.

The third thickness compensation pattern TCP3 may be arranged in the first sub-pixel area SPA1 on the first pixel electrode PE1. The resonance thickness of light emitted from the first light-emitting element LD1 may be controlled by the third thickness compensation pattern TCP3. The third thickness compensation pattern TCP3 may have substantially the same structure as the second thickness compensation pattern TCP2 of FIG. 9. That is, the third thickness compensation pattern TCP3 may have a structure in which an insulating pattern and a conductive pattern, respectively including the same material as the third insulating pattern ILP3 and the third conductive pattern CDP3 of FIG. 9, are stacked.

The first anode connection pattern ACP1 may be arranged on the third pixel electrode PE3, the second anode connection pattern ACP2 may be arranged on the second pixel electrode PE2, and the third anode connection pattern ACP3 may be arranged on the first pixel electrode PE1. The first to third anode connection patterns ACP1, ACP2, and ACP3 may cover a side surface of the first thickness compensation pattern TCP1, a side surface of the second thickness compensation pattern TCP2, and a side surface of the third thickness compensation pattern TCP3, respectively. The first anode connection pattern ACP1 may electrically connect the third pixel electrode PE3 and a conductive pattern included in the first thickness compensation pattern TCP1 to each other. The second anode connection pattern ACP2 may electrically connect the second pixel electrode PE2 and a conductive pattern included in the second thickness compensation pattern TCP2 to each other. The third anode connection pattern ACP3 may electrically connect the first pixel electrode PE1 and a conductive pattern included in the third thickness compensation pattern TCP3 to each other.

The first pixel electrode PE1 and the third thickness compensation pattern TCP3 may be defined as a first anode. The second pixel electrode PE2 and the second thickness compensation pattern TCP2 may be defined as a second anode. The third pixel electrode PE3 and the first thickness compensation pattern TCP1 may be defined as a third anode. A total thickness of the first anode may be controlled by the third thickness compensation pattern TCP3. A total thickness of the second anode may be controlled by the second thickness compensation pattern TCP2. A total thickness of the third anode may be controlled by the first thickness compensation pattern TCP1. The total thickness of the third anode may be different from the total thickness of the first anode and the total thickness of the second anode. For example, the total thickness of the third anode may be greater than the total thickness of the first anode and the total thickness of the second anode. The total thickness of the first anode and the total thickness of the second anode may be equal to each other.

In one or more embodiment, a display device includes sub-pixel areas including light emitting elements which emit different color lights from each other, and a first light emitting element (like LD3) among the light emitting elements which is in a first sub-pixel area (like SPA3) among the sub-pixel areas, the first light emitting element including a first anode (PE, TCP and ACP together), a first light-emitting layer (like OL at SPA3) which is on the first anode. The first anode includes a first pixel electrode (like PE3), a first thickness compensation pattern (like TCP1) overlapping the first pixel electrode, the first thickness compensation pattern including a first insulating pattern ILP1, a first conductive pattern CDP1, a second insulating pattern ILP2 and a second conductive pattern CDP2 in order from the first pixel electrode, and a first anode connection pattern ACP1 which covers a side surface of the first thickness compensation pattern TCP1 and electrically connects the first pixel electrode, the first conductive pattern and the second conductive pattern to each other.

The first anode connection pattern may contact the first pixel electrode at an edge thereof and expose the second conductive pattern CDP2 to outside the first anode.

The display device may further include a second light emitting element (like LD2) among the light emitting elements which is in a second sub-pixel area (like SPA2) among the sub-pixel areas. The second light emitting element may include a second anode, and a second light-emitting layer which is on the second anode. The second anode may include a second pixel electrode (like PE2), a second thickness compensation pattern (like TCP2) overlapping the second pixel electrode, the second thickness compensation pattern including a third insulating pattern (like ILP3) and a third conductive pattern (like CDP3) in order from the second pixel electrode, and a second anode connection pattern (like ACP2) which covers a side surface of the second thickness compensation pattern and electrically connects the second pixel electrode and the third conductive pattern to each other. The second conductive pattern CDP2 of the first anode may be exposed to outside the first anode and in contact with the first light-emitting layer together with the third conductive pattern CDP3 of the second anode being exposed to outside the second anode and being in contact with the second light-emitting layer.

The display device may further include a third light emitting element (like LD1) among the light emitting elements which is in a third sub-pixel area (like SPA1) among the sub-pixel areas. The third light emitting element may include a third anode (like PE1 only), a third light-emitting layer which is on the third anode, and the third anode including a third pixel electrode. The second conductive pattern CDP2 of the first anode may be exposed to outside the first anode and in contact with the first light-emitting layer together with the third pixel electrode of the third anode being exposed to outside the third anode and being in contact with the third light-emitting layer.

FIGS. 13, 14, 15, 16, 17, 18, 19, 20, and 21 are cross-sectional views illustrating a method of manufacturing (or providing) a display device according to an embodiment of the present disclosure. The method of manufacturing the display device described with reference to FIGS. 13 to 21 may be a method of manufacturing the display device DD2 described above with reference to FIGS. 8 and 9. Hereinafter, redundant descriptions of the display device DD2 described above with reference to FIGS. 8 and 9 may be omitted or may be summarized.

In FIGS. 13 to 21, a method of manufacturing (or providing) a display device DD2 having a configuration substantially identical or similar to the display device DD2 described above with reference to FIGS. 8 and 9 is described, but a person skilled in the art will understand that any one of the display devices DD, DD′, DD2′, and DD3 described above with reference to FIGS. 2, 6, 10, and 12 can be manufactured by making obvious changes in a process such as a patterning process.

Referring to FIG. 13, the first pixel electrode PE1 overlapping the first sub-pixel area SPA1, the second pixel electrode PE2 overlapping the second sub-pixel area SPA2, and the third pixel electrode PE3 overlapping the third sub-pixel area SPA3 may be formed (or provided) on the substrate SUB to provide a stacked structure (S100). For example, the first to third pixel electrodes PE1, PE2, and PE3 may be formed on the via-insulating layer VIA and spaced apart from each other. Descriptions of a method of forming the first to third transistors TR1, TR2, and TR3, the buffer layer BUF, the gate insulating layer GI, the inter-layer insulating layer ILD, and the via-insulating layer VIA is omitted.

Each of the first to third pixel electrodes PE1, PE2, and PE3 may have a single-layer structure or a multi-layer structure. In an embodiment, each of the first to third pixel electrodes PE1, PE2, and PE3 may have a multi-layer structure including a plurality of conductive layers.

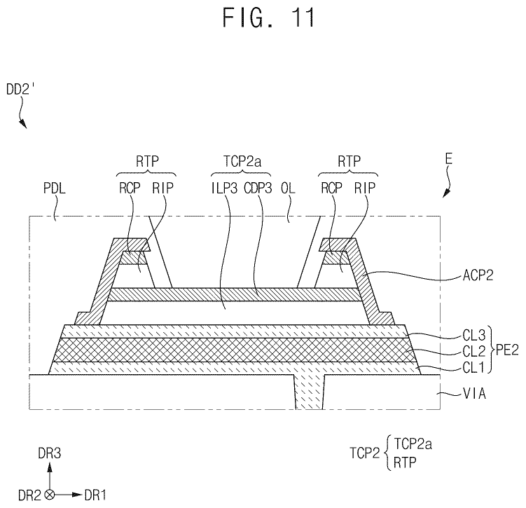

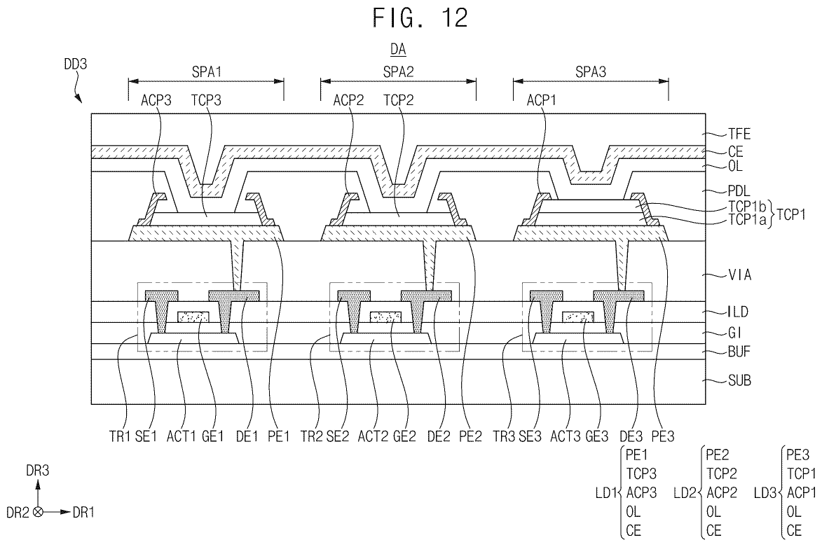

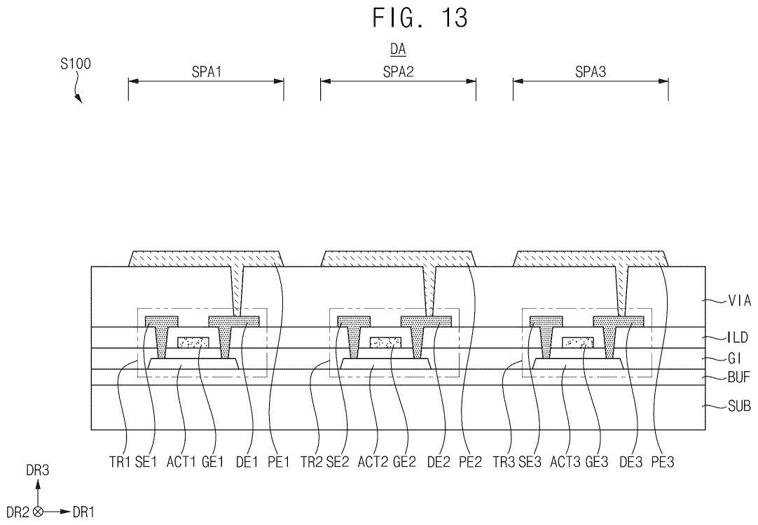

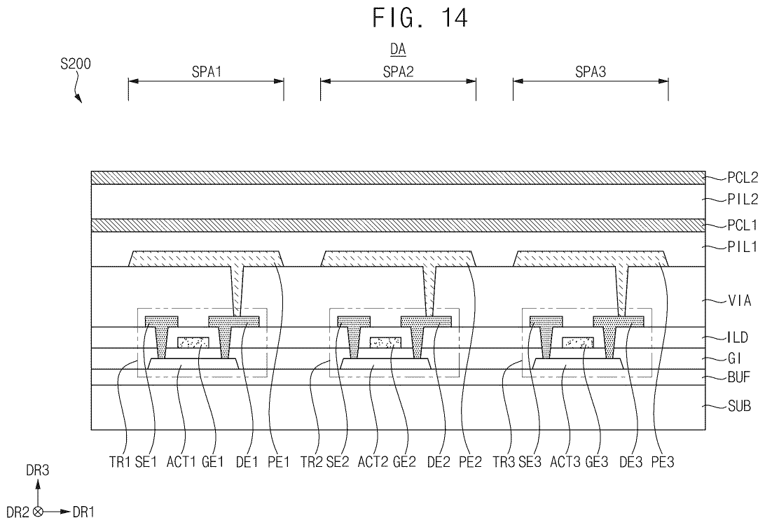

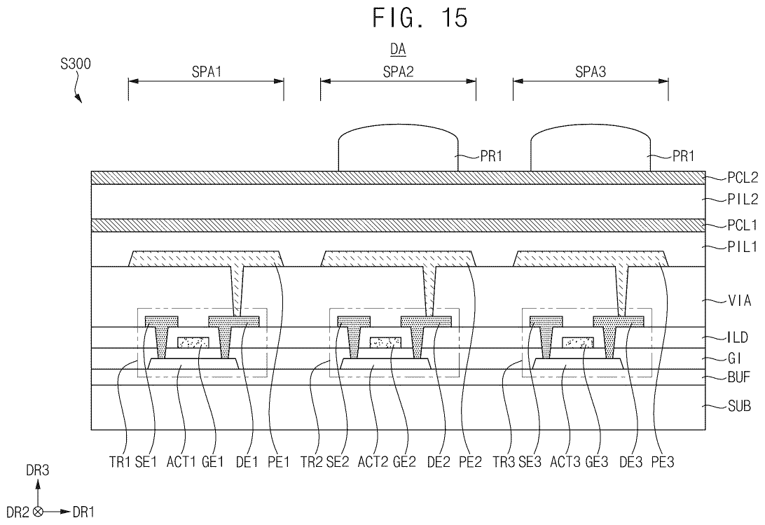

Referring to FIG. 14, a first preliminary insulating layer PIL1 covering the first to third pixel electrodes PE1, PE2, and PE3 may be formed on the substrate SUB (S200). For example, the first preliminary insulating layer PIL1 may be formed on the via-insulating layer VIA. The first preliminary insulating layer PIL1 may be formed in the display area DA. That is, the first preliminary insulating layer PIL1 may be entirely formed over the first to third sub-pixel areas SPA1, SPA2, and SPA3. In addition, a first preliminary conductive layer PCL1, a second preliminary insulating layer PIL2, and a second preliminary conductive layer PCL2 may be sequentially formed on the first preliminary insulating layer PIL1 (S200). The first preliminary conductive layer PCL1, the second preliminary insulating layer PIL2, and the second preliminary conductive layer PCL2 may be formed in the display area DA. That is, a preliminary thickness compensation structure including the first preliminary conductive layer PCL1, the second preliminary insulating layer PIL2, and the second preliminary conductive layer PCL2 may be entirely formed over the first to third sub-pixel areas SPA1, SPA2, and SPA3.

Each of the first preliminary insulating layer PIL1 and the second preliminary insulating layer PIL2 may include a material having a low light absorption coefficient. For example, each of the first preliminary insulating layer PIL1 and the second preliminary insulating layer PIL2 may include silicon oxide (SiOₓ), silicon nitride (SiNₓ), or the like. In an embodiment, each of the first preliminary insulating layer PIL1 and the second preliminary insulating layer PIL2 may include silicon dioxide (SiO₂). The preliminary insulating layers may have a light absorption coefficient which is lower than that of the preliminary conductive layers.

Each of the first preliminary conductive layer PCL1 and the second preliminary conductive layer PCL2 may include a transparent conductive oxide. For example, each of the first preliminary conductive layer PCL1 and the second preliminary conductive layer PCL2 may include indium tin oxide (ITO), indium zinc oxide (IZO), or the like. In an embodiment, each of the first preliminary conductive layer PCL1 and the second preliminary conductive layer PCL2 may include indium tin oxide (ITO).

In an embodiment, a thickness of each of the first preliminary insulating layer PIL1 and a thickness of the second preliminary insulating layer PIL2 may be greater than a thickness of the first preliminary conductive layer PCL1 and a thickness of the second preliminary conductive layer PCL2. For example, the thickness of each of the first preliminary insulating layer PIL1 and the second preliminary insulating layer PIL2 may be about 300 Å, and the thickness of each of the first preliminary conductive layer PCL1 and the second preliminary conductive layer PCL2 may be about 70 Å, but the present disclosure is not necessarily limited thereto.

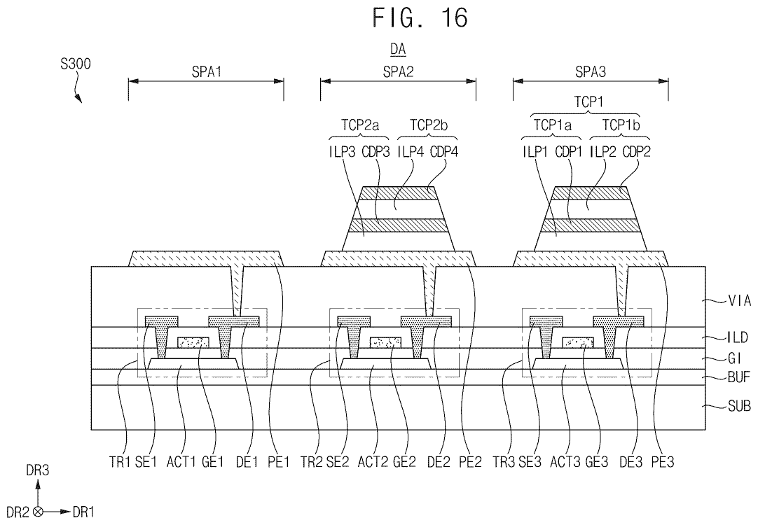

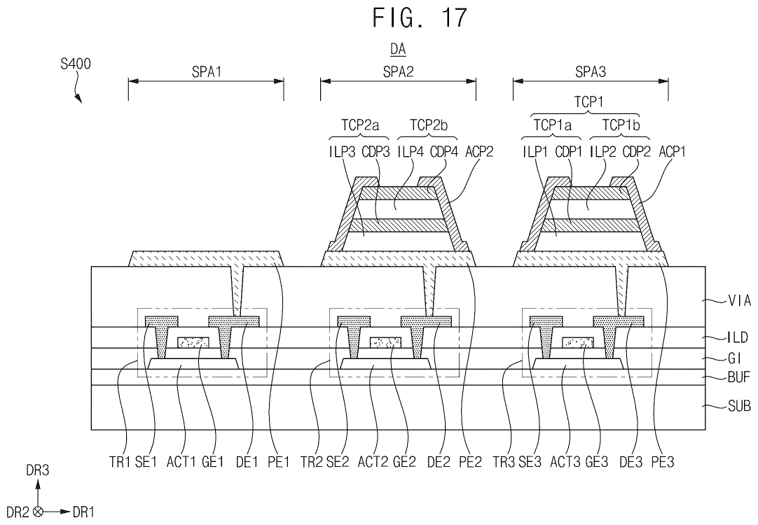

Referring to FIGS. 15 and 16, the first thickness compensation pattern TCP1 may be formed by etching the stack of the first preliminary insulating layer PIL1, the first preliminary conductive layer PCL1, the second preliminary insulating layer PIL2, and the second preliminary conductive layer PCL2 through a first etching process (S300).

As illustrated in FIG. 15, a first photoresist pattern PR1 may be formed on the second preliminary conductive layer PCL2. The first photoresist pattern PR1 may be formed by applying a photosensitive organic film on the second preliminary conductive layer PCL2 and performing an exposure process using a photomask. For example, through the exposure process, a portion of the photosensitive organic film overlapping the second sub-pixel area SPA2 and the third sub-pixel area SPA3 may remain, thereby forming the first photoresist pattern PR1. That is, the first photoresist pattern PR1 may overlap the second pixel electrode PE2 and the third pixel electrode PE3 in a plan view. For example, an upper surface of the first photoresist pattern PR1 may have a convex shape in a cross-section. The first photoresist pattern PR1 may include portions corresponding to the thickness compensation patterns of the second sub-pixel area SPA2 and the third sub-pixel area SPA3.

As illustrated in FIG. 16, the first preliminary insulating layer PIL1, the first preliminary conductive layer PCL1, the second preliminary insulating layer PIL2, and the second preliminary conductive layer PCL2 may be patterned through the first etching process using the first photoresist pattern PR1 as a mask. Accordingly, a portion of the first preliminary insulating layer PIL1, a portion of the first preliminary conductive layer PCL1, a portion of the second preliminary insulating layer PIL2, and a portion of the second preliminary conductive layer PCL2 which are adjacent to and/or spaced apart from the first photoresist pattern PR1 in a plan view may be removed. That is, a portion of the first preliminary insulating layer PIL1, a portion of the first preliminary conductive layer PCL1, a portion of the second preliminary insulating layer PIL2, and a portion of the second preliminary conductive layer PCL2 overlapping the first photoresist pattern PR1 in a plan view may remain as preliminary thickness compensation patterns in the respective sub-pixel areas. In the first etching process, the first to third pixel electrodes PE1, PE2, and PE3 may not be etched. As such, a thickness and/or a shape of the respective pixel electrodes may be unchanged after the first etching process, without being limited thereto.

In an embodiment, the first preliminary conductive layer PCL1 and the second preliminary conductive layer PCL2 may be patterned through a wet etching process, and the first preliminary insulating layer PIL1 and the second preliminary insulating layer PIL2 may be patterned through a dry etching process. However, the present disclosure is not necessarily limited thereto. In an embodiment, the first preliminary insulating layer PIL1, the first preliminary conductive layer PCL1, the second preliminary insulating layer PIL2, and the second preliminary conductive layer PCL2 may be patterned through a wet etching process.

Through the first etching process, the first thickness compensation pattern TCP1 may be formed. The first thickness compensation pattern TCP1 may overlap the third sub-pixel area SPA3 and may include the first insulating pattern ILP1, the first conductive pattern CDP1, the second insulating pattern ILP2, and the second conductive pattern CDP2 which are sequentially stacked on the third pixel electrode PE3. The first insulating pattern ILP1 and the first conductive pattern CDP1 may form the first lower thickness compensation pattern TCP1a, and the second insulating pattern ILP2 and the second conductive pattern CDP2 may form the first upper thickness compensation pattern TCP1b.

Through the first etching process, the third insulating pattern ILP3, the third conductive pattern CDP3, a fourth insulating pattern ILP4, and a fourth conductive pattern CDP4 which overlap the second sub-pixel area SPA2 and are sequentially stacked on the second pixel electrode PE2 may be formed as a preliminary second thickness compensation pattern. The third insulating pattern ILP3 and the third conductive pattern CDP3 may form the second lower thickness compensation pattern TCP2a, and the fourth insulating pattern ILP4 and the fourth conductive pattern CDP4 may form a second upper thickness compensation pattern TCP2b. Here, the etching of the first preliminary insulating layer, the first preliminary conductive layer, the second preliminary insulating layer and the second preliminary conductive layer through the first etching process may further respectively form a third insulating pattern, a third conductive pattern, a fourth insulating pattern, and a fourth conductive pattern of a second thickness compensation pattern of the second anode.

That is, the third insulating pattern ILP3 and the first insulating pattern ILP1 may include the same material and may be formed through the same process. The third conductive pattern CDP3 and the first conductive pattern CDP1 may include the same material and may be formed through the same process. The fourth insulating pattern ILP4 and the second insulating pattern ILP2 may include the same material and may be formed through the same process. The fourth conductive pattern CDP4 and the second conductive pattern CDP2 may include the same material and may be formed through the same process.

Through the first etching process, the first preliminary insulating layer PIL1, the first preliminary conductive layer PCL1, the second preliminary insulating layer PIL2, and the second preliminary conductive layer PCL2 overlapping the first sub-pixel area SPA1 may be removed.

After the first preliminary insulating layer PIL1, the first preliminary conductive layer PCL1, the second preliminary insulating layer PIL2, and the second preliminary conductive layer PCL2 are patterned through the first etching process using the first photoresist pattern PR1 as a mask, the first photoresist pattern PR1 may be removed.

In an embodiment, after the first preliminary insulating layer PIL1, the first preliminary conductive layer PCL1, the second preliminary insulating layer PIL2, and the second preliminary conductive layer PCL2 are patterned, a portion of each of the first to fourth insulating patterns ILP1, ILP2, ILP3, and ILP4 may be removed through an additional etching process. For example, a portion of a side surface of each of the first to fourth insulating patterns ILP1, ILP2, ILP3, and ILP4 may be removed. Accordingly, as described above with reference to FIGS. 6 and 7, the side surface of each of the first to fourth insulating patterns ILP1, ILP2, ILP3, and ILP4 may have a recessed structure. Here, the removing of the portions may provide the first conductive pattern CDP1 protruding further than the side surface of the first insulating pattern ILP1 together with the second conductive pattern CDP2 protruding further than the side surface of the second insulating pattern ILP2.

Referring to FIG. 17, an anode connection pattern (e.g., the first anode connection pattern ACP1) covering a side surface of the first thickness compensation pattern TCP1 and contacting the third pixel electrode PE3, the first conductive pattern CDP1, and the second conductive pattern CDP2 may be formed (S400). For example, the first anode connection pattern ACP1 may be patterned through a wet etching process.

The first anode connection pattern ACP1 may be formed on the third pixel electrode PE3 in the third sub-pixel area SPA3. The first anode connection pattern ACP1 may contact the edge of the third pixel electrode PE3. In an embodiment, the first anode connection pattern ACP1 may be spaced apart from the central portion of the third pixel electrode PE3 in a plan view.

The first anode connection pattern ACP1 may cover the side surface of the first thickness compensation pattern TCP1. In an embodiment, the first anode connection pattern ACP1 may entirely surround the first thickness compensation pattern TCP1 in a plan view. The first anode connection pattern ACP1 may contact the side surface of the first insulating pattern ILP1, the side surface of the first conductive pattern CDP1, the side surface of the second insulating pattern ILP2, and the side surface of the second conductive pattern CDP2. In addition, the first anode connection pattern ACP1 may contact the upper surface of the second conductive pattern CDP2. The first anode connection pattern ACP1 may electrically connect the third pixel electrode PE3, the first conductive pattern CDP1, and the second conductive pattern CDP2.

The second anode connection pattern ACP2 may be formed on the second pixel electrode PE2 in the second sub-pixel area SPA2. The second anode connection pattern ACP2 may contact the edge of the second pixel electrode PE2. In an embodiment, the second anode connection pattern ACP2 may be spaced apart from the central portion of the second pixel electrode PE2 in a plan view.

The second anode connection pattern ACP2 may contact the side surface of the third insulating pattern ILP3, the side surface of the third conductive pattern CDP3, a side surface of the fourth insulating pattern ILP4, and a side surface of the fourth conductive pattern CDP4. In addition, the second anode connection pattern ACP2 may contact an upper surface of the fourth conductive pattern CDP4. The second anode connection pattern ACP2 may electrically connect the second pixel electrode PE2 and the third conductive pattern CDP3.

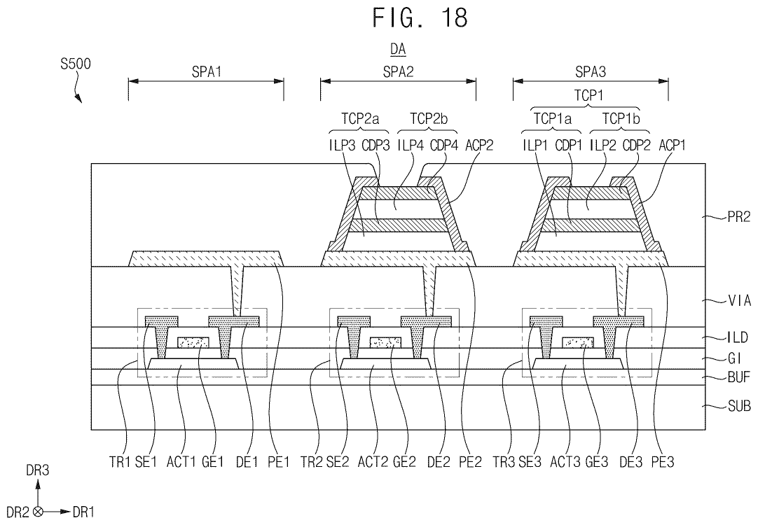

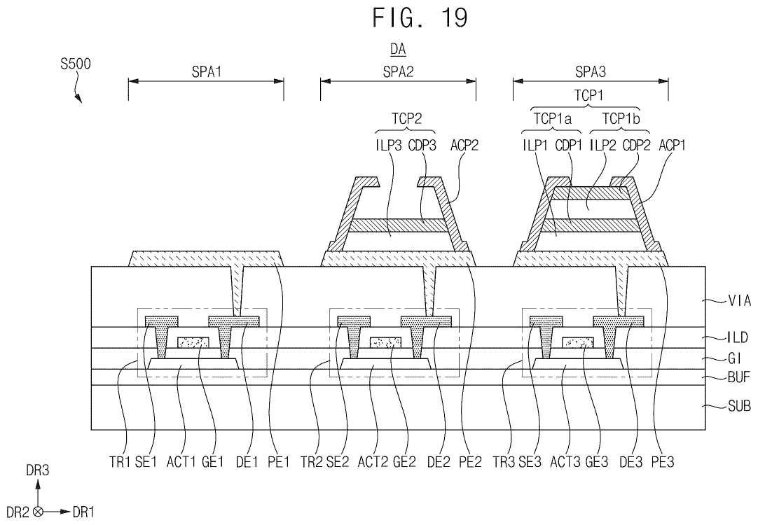

Referring to FIGS. 18 and 19, the fourth insulating pattern ILP4 and the fourth conductive pattern CDP4 may be removed through a second etching process (S500).

As illustrated in FIG. 18, a second photoresist pattern PR2 may be formed on the via-insulating layer VIA. The second photoresist pattern PR2 may be entirely formed over the first to third sub-pixel areas SPA1, SPA2, and SPA3. The second photoresist pattern PR2 may cover the first pixel electrode PE1, the second pixel electrode PE2, the third pixel electrode PE3, the first thickness compensation pattern TCP1, and the first anode connection pattern ACP1. That is, the second photoresist pattern PR2 may protect the first to third pixel electrodes PE1, PE2, and PE3, the first thickness compensation pattern TCP1, and the first anode connection pattern ACP1 from an etchant.

In an embodiment, the second photoresist pattern PR2 may cover the second anode connection pattern ACP2 and expose a portion of the upper surface of the fourth conductive pattern CDP4. That is, the second photoresist pattern PR2 may protect the second anode connection pattern ACP2 from the etchant used in the second etching process.

As illustrated in FIG. 19, the fourth insulating pattern ILP4 and the fourth conductive pattern CDP4 within the preliminary second thickness compensation pattern may be removed through the second etching process using the second photoresist pattern PR2 as a mask.

In an embodiment, the fourth conductive pattern CDP4 may be removed through a wet etching process, and the fourth insulating pattern ILP4 may be removed through a dry etching process. However, the present disclosure is not necessarily limited thereto. In an embodiment, the fourth conductive pattern CDP4 and the fourth insulating pattern ILP4 may be removed through a wet etching process.

Through the second etching process, the fourth insulating pattern ILP4 and the fourth conductive pattern CDP4 may be removed, and the second thickness compensation pattern TCP2 including the third insulating pattern ILP3 and the third conductive pattern CDP3 may be formed.

In an embodiment, the second etching process may be an isotropic etching process. In this case, as illustrated in FIG. 19, the second anode connection pattern ACP2 may be spaced apart from the upper surface of the second thickness compensation pattern TCP2 (specifically, the upper surface of the third conductive pattern CDP3). That is, a spaced space SPS as an empty space may be formed between the second anode connection pattern ACP2 and the second thickness compensation pattern TCP2.

In an embodiment, the second etching process may be an anisotropic etching process. In this case, as described above with reference to FIGS. 10 and 11, a portion of the fourth insulating pattern ILP4 and a portion of the fourth conductive pattern CDP4 overlapping the second anode connection pattern ACP2 in a plan view may not be removed. In other words, after the second etching process, a portion of the fourth insulating pattern ILP4 and a portion of the fourth conductive pattern CDP4 may remain, and the residual pattern (RTP, refer to FIG. 11) may be formed. Here, the removing of the portions of the fourth insulating pattern and the fourth conductive pattern may form residual patterns of the fourth insulating pattern and the fourth conductive pattern at an edge of the third conductive pattern.

After the fourth insulating pattern ILP4 and the fourth conductive pattern CDP4 are removed through the second etching process using the second photoresist pattern PR2 as a mask, the second photoresist pattern PR2 may be removed.

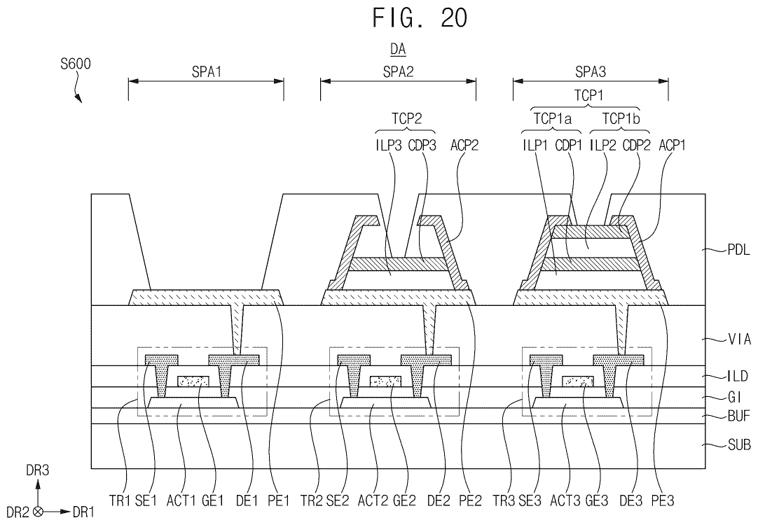

Referring to FIG. 20, the pixel defining layer PDL may be formed on the via-insulating layer VIA (S600). An opening which exposes an upper surface of each of the first pixel electrode PE1, the first thickness compensation pattern TCP1, and the second thickness compensation pattern TCP2 may be defined in the pixel defining layer PDL. The pixel defining layer PDL may cover the first anode connection pattern ACP1 and the second anode connection pattern ACP2. In an embodiment, the pixel defining layer PDL may occupy a portion of the empty space under the second anode connection pattern ACP2.

The pixel openings which are defined in the pixel defining layer PDL expose an uppermost surface of the various anode electrodes to outside the pixel defining layer PDL. The uppermost surface may be defined by a pixel electrode or by a thickness compensation pattern, namely a conductive layer of one of these elements.

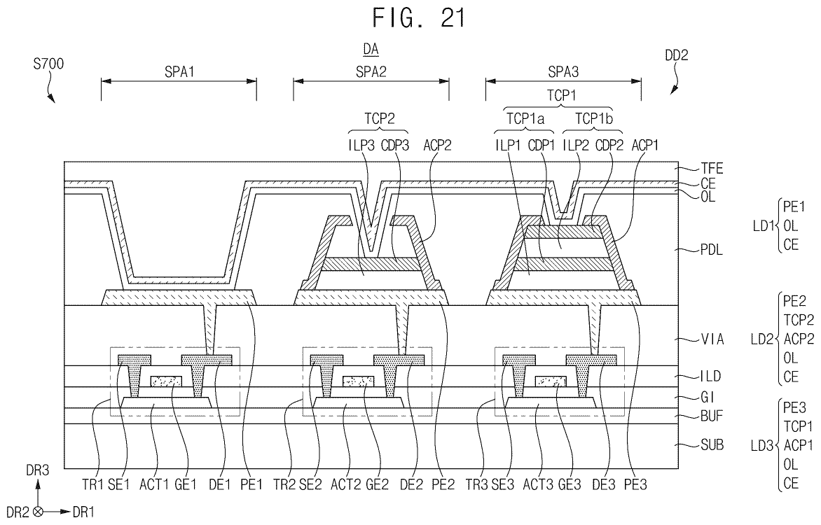

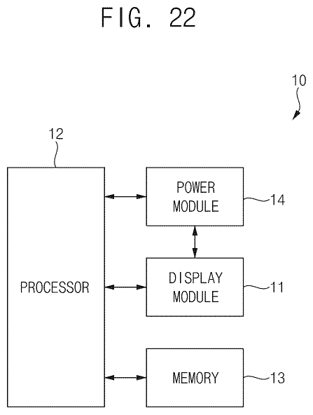

Referring to FIG. 21, the organic layer OL may be formed on the pixel defining layer PDL, the first pixel electrode PE1, the second pixel electrode PE2, and the third pixel electrode PE3 (S700). For example, the organic layer OL may be formed on the second thickness compensation pattern TCP2 in the second sub-pixel area SPA2 and may be formed on the first thickness compensation pattern TCP1 in the third sub-pixel area SPA3. The organic layer OL may continuously extend over the first sub-pixel area SPA1, the second sub-pixel area SPA2, and the third sub-pixel area SPA3. The organic layer OL may contact the exposed surface of the anodes.

The organic layer OL may include the first light-emitting layer (EML1, refer to FIG. 5), the second light-emitting layer (EML2, refer to FIG. 5), and the third light-emitting layer (EML3, refer to FIG. 5). The first light-emitting layer EML1 may be formed on the first pixel electrode PE1, the second light-emitting layer EML2 may be formed on the second pixel electrode PE2, and the third light-emitting layer EML3 may be formed on the third pixel electrode PE3. In an embodiment, the first light-emitting layer EML1 may overlap the first sub-pixel area SPA1, the second light-emitting layer EML2 may overlap the first to third sub-pixel areas SPA1, SPA2, and SPA3, and the third light-emitting layer EML3 may overlap the third sub-pixel area SPA3.

The first light-emitting layer EML1, the second light-emitting layer EML2, and the third light-emitting layer EML3 may emit light having different colors. That is, the first light-emitting layer EML1 may emit a first light, the second light-emitting layer EML2 may emit a second light having a different color from a color of the first light, and the third light-emitting layer EML3 may emit a third light having a different color from the color of the first light and a color of the second light. For example, the first light may be red light, the second light may be green light, and the third light may be blue light. However, the present disclosure is not necessarily limited thereto.

The common electrode CE may be formed on the organic layer OL. The common electrode CE may continuously extend over the first to third sub-pixel areas SPA1, SPA2, and SPA3. The common electrode CE may be formed along the profile of the organic layer OL with a substantially uniform thickness.

The encapsulation layer TFE may be formed on the common electrode CE. The encapsulation layer TFE may prevent impurities, moisture, or the like from penetrating into the first to third light-emitting elements LD1, LD2, and LD3 from the outside. The encapsulation layer TFE may include at least one inorganic encapsulation layer and at least one organic encapsulation layer. Accordingly, one or more embodiments of the display devices disclosed herein may be formed.

In one or more embodiment, a method of providing a display device includes providing light emitting elements respectively in sub-pixel areas emitting different color lights from each other, the light emitting elements including a first pixel electrode of a first anode which overlaps a first sub-pixel area among the sub-pixel areas, and a second pixel electrode of a second anode which overlaps a second sub-pixel area among the sub-pixel areas, providing a first preliminary insulating layer covering the first pixel electrode and the second pixel electrode (FIG. 13), sequentially providing a first preliminary conductive layer, a second preliminary insulating layer and a second preliminary conductive layer in order from the first preliminary insulating layer (FIG. 14), etching the first preliminary insulating layer, the first preliminary conductive layer, the second preliminary insulating layer and the second preliminary conductive layer through a first etching process to respectively form a first insulating pattern, a first conductive pattern, a second insulating pattern and a second conductive pattern of a first thickness compensation pattern of the first anode (FIGS. 15 and 16), providing a first anode connection pattern of the first anode which covers a side surface of the first thickness compensation pattern and electrically connects the first pixel electrode the first conductive pattern and the second conductive pattern to each other (FIG. 17), and providing a first light-emitting layer on the first anode having the first pixel electrode, the first thickness compensation pattern and the first anode connection pattern (FIG. 21).

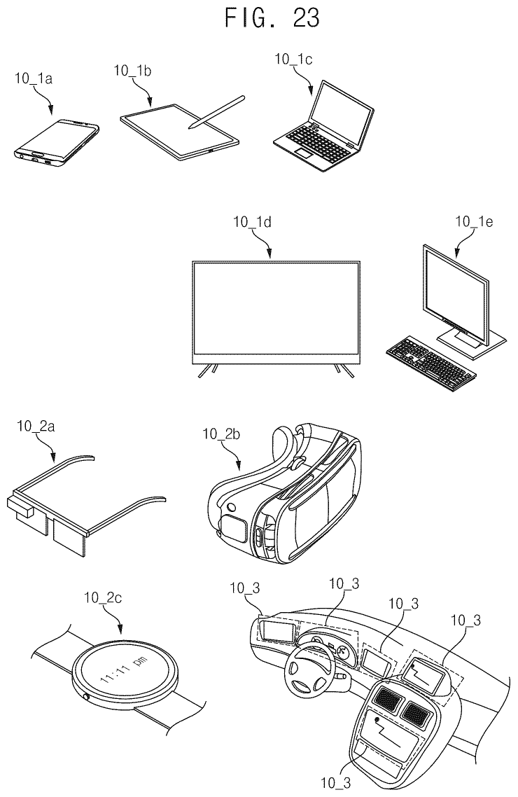

FIG. 22 is a block diagram of an electronic device 10 according to an embodiment of the present disclosure.

Referring to FIG. 22, an electronic device 10 according to an embodiment may include a display module 11, a processor 12, a memory 13, and a power module 14. The display device according to an embodiment may be applied to a variety of electronic devices. The electronic device 10 according to an embodiment may include one or more of the embodiments of the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module which converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules which are functionally included in one module may be included in the display device and others may be provided separately from the display device. For example, the display device may include the display module 11, and the processor 12, the memory 13, and the power module 14 may be provided in the form of other devices in the electronic device 10 other than the display device.

FIG. 23 is a schematic view of an electronic device 10 according to various embodiments.

Referring to FIG. 23, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
sub-pixel areas comprising light emitting elements which emit different color lights from each other; and
a first light emitting element among the light emitting elements which is in a first sub-pixel area among the sub-pixel areas, the first light emitting element comprising:
a first anode;
a first light-emitting layer which is on the first anode; and
the first anode comprising:
a first pixel electrode;
a first thickness compensation pattern overlapping the first pixel electrode, the first thickness compensation pattern comprising a first insulating pattern, a first conductive pattern, a second insulating pattern and a second conductive pattern in order from the first pixel electrode; and
a first anode connection pattern which covers a side surface of the first thickness compensation pattern and electrically connects the first pixel electrode, the first conductive pattern and the second conductive pattern to each other.

2. The display device of claim 1, wherein within the first anode, a thickness of the first insulating pattern and a thickness of the second insulating pattern are each greater than a thickness of the first conductive pattern and a thickness of the second conductive pattern.

3. The display device of claim 1, wherein within the first anode,
each of the first insulating pattern and the second insulating pattern comprises a silicon oxide, and
each of the first conductive pattern and the second conductive pattern comprises a transparent conductive oxide.

4. The display device of claim 1, wherein the first anode connection pattern surrounds the first thickness compensation pattern.

5. The display device of claim 1, wherein the first anode connection pattern contacts the first pixel electrode at an edge thereof and exposes the second conductive pattern to outside the first anode.

6. The display device of claim 1, wherein within the first anode,
the first conductive pattern protrudes further than a side surface of the first insulating pattern to define a protruded portion of the first conductive pattern, and
the second conductive pattern protrudes further than a side surface of the second insulating pattern to define a protruded portion of the second conductive pattern.

7. The display device of claim 6, wherein the first anode connection pattern contacts a lower surface of protruded portion of the first conductive pattern and a lower surface of the protruded portion of the second conductive pattern.

8. The display device of claim 1, further comprising a second light emitting element among the light emitting elements which is in a second sub-pixel area among the sub-pixel areas,
wherein
the second light emitting element comprises:
a second anode;
a second light-emitting layer which is on the second anode; and
the second anode comprising:
a second pixel electrode;
a second thickness compensation pattern overlapping the second pixel electrode, the second thickness compensation pattern comprising a third insulating pattern and a third conductive pattern in order from the second pixel electrode; and
a second anode connection pattern which covers a side surface of the second thickness compensation pattern and electrically connects the second pixel electrode and the third conductive pattern to each other; and
the second conductive pattern of the first anode is exposed to outside the first anode and is in contact with the first light-emitting layer together with the third conductive pattern of the second anode being exposed to outside the second anode and being in contact with the second light-emitting layer.

9. The display device of claim 8, wherein
the sub-pixel areas further comprise an insulating layer and a conductive layer;
the insulating layer defines both the first insulating pattern of the first anode and the third insulating pattern of the second anode, and
the conductive layer defines both the first conductive pattern of the first anode and the third conductive pattern of the second anode.

10. The display device of claim 8, wherein along a thickness direction of the second anode, the second anode connection pattern is spaced apart from an upper surface of the second thickness compensation pattern.

11. The display device of claim 8, wherein within the second anode, the second thickness compensation pattern further comprises:
a residual insulating pattern and a residual conductive pattern in order from the third conductive pattern;
each of the residual insulating pattern and the residual conductive pattern overlapping an edge of the third conductive pattern.

12. The display device of claim 11, wherein the second anode connection pattern overlaps an entirety of the residual insulating pattern and an entirety of the residual conductive pattern in a plan view.

13. The display device of claim 1, a third light emitting element among the light emitting elements which is in a third sub-pixel area among the sub-pixel areas,
wherein
the third light emitting element comprises:
a third anode;
a third light-emitting layer which is on the third anode; and
the third anode comprising a third pixel electrode; and
the second conductive pattern of the first anode is exposed to outside the first anode and is in contact with the first light-emitting layer together with the third pixel electrode of the third anode being exposed to outside the third anode and being in contact with the third light-emitting layer.

14. A method of providing a display device, the method comprising:
providing light emitting elements respectively in sub-pixel areas emitting different color lights from each other, the light emitting elements including:
a first pixel electrode of a first anode which overlaps a first sub-pixel area among the sub-pixel areas, and
a second pixel electrode of a second anode which overlaps a second sub-pixel area among the sub-pixel areas;
providing a first preliminary insulating layer covering the first pixel electrode and the second pixel electrode;
sequentially providing a first preliminary conductive layer, a second preliminary insulating layer and a second preliminary conductive layer in order from the first preliminary insulating layer;
etching the first preliminary insulating layer, the first preliminary conductive layer, the second preliminary insulating layer and the second preliminary conductive layer through a first etching process to respectively form a first insulating pattern, a first conductive pattern, a second insulating pattern and a second conductive pattern of a first thickness compensation pattern of the first anode;
providing a first anode connection pattern of the first anode which covers a side surface of the first thickness compensation pattern and electrically connects the first pixel electrode the first conductive pattern and the second conductive pattern to each other; and
providing a first light-emitting layer on the first anode having the first pixel electrode, the first thickness compensation pattern and the first anode connection pattern.

15. The method of claim 14, wherein a thickness of the first preliminary insulating layer and a thickness of the second preliminary insulating layer are each greater than a thickness of the first preliminary conductive layer and a thickness of the second preliminary conductive layer.

16. The method of claim 14, further comprising:
removing a portion of a side surface of the first insulating pattern and a portion of a side surface of the second insulating pattern through an additional etching process after forming of the first thickness compensation pattern of the first anode,
wherein the removing of the portions provides the first conductive pattern protruding further than the side surface of the first insulating pattern together with the second conductive pattern protruding further than the side surface of the second insulating pattern.

17. The method of claim 14, wherein the etching of the first preliminary insulating layer, the first preliminary conductive layer, the second preliminary insulating layer and the second preliminary conductive layer through the first etching process further respectively forms a third insulating pattern, a third conductive pattern, a fourth insulating pattern, and a fourth conductive pattern of a second thickness compensation pattern of the second anode.

18. The method of claim 17, further comprising:
removing a portion of the fourth insulating pattern and a portion of the fourth conductive pattern through a second etching process.

19. The method of claim 18, wherein
the second etching process is an anisotropic etching process, and
the removing of the portions of the fourth insulating pattern and the fourth conductive pattern forms residual patterns of the fourth insulating pattern and the fourth conductive pattern at an edge of the third conductive pattern.

20. An electronic device comprising:
a display device comprising sub-pixel areas which emit different color lights from each other; and
a processor configured to transmit an image data signal and an input control signal to the display device,
wherein the display device further comprises:
light emitting elements in the sub-pixel areas;
a light emitting element among the light emitting elements which is in a sub-pixel area among the sub-pixel areas, the light emitting element comprising:
an anode;
a light-emitting layer which is on the anode; and
the anode comprising:
a pixel electrode;
a thickness compensation pattern overlapping the pixel electrode, the thickness compensation pattern comprising a first insulating pattern, a first conductive pattern, a second insulating pattern and a second conductive pattern in order from the pixel electrode; and
an anode connection pattern which covers a side surface of the thickness compensation pattern and electrically connects the pixel electrode, the first conductive pattern and the second conductive pattern to each other,
wherein the second conductive pattern of the anode is exposed to outside the anode and is in contact the light-emitting layer.
